(19) United States
(12) Patent Application Publication
(10) Pub. No.: US 2026/0082900 A1
(43) Pub. Date: Mar. 19, 2026

(54) INTERCONNECT STRUCTURE AND METHODS OF FORMING THE SAME

(71) Applicant: TAIWAN SEMICONDUCTOR MANUFACTURING COMPANY, LTD., Hsinchu (TW)

(72) Inventors: Chia-Pang KUO, Taoyuan (TW); Yen-Chun LIN, Hsinchu (TW); Jen-Wei LIU, Taipei (TW); Ming-Chou CHIANG, Hsinchu (TW); Cheng-Hui WENG, Hsinchu (TW)

(21) Appl. No.: 18/888,276

(22) Filed: Sep. 18, 2024

(51) Int. Cl. H01L 23/532; H01L 21/768; H01L 23/528

(52) U.S. Cl. CPC H10W 20/4403; H10W 20/032; H10W 20/435

(57) ABSTRACT

In some embodiments, an interconnect structure includes a first conductive structure disposed in a first dielectric layer, wherein the first conductive structure includes a first barrier layer and a first main conductive layer; a second dielectric layer disposed over the first dielectric layer; and a second conductive structure disposed in the second dielectric layer and over the first conductive structure, wherein the second conductive structure includes: a second barrier layer including a first conductive material selected from Ru or Mo; a second main conductive layer disposed over the second barrier layer and including a second conductive material; and a third conductive material being a dopant doped in the second main conductive layer or being a continuous layer between the second main conductive layer and the second barrier layer, wherein the third conductive material is selected from Mn, Ti, Co, Ru, Al, Zn, In, or combinations thereof.

### BACKGROUND

As the semiconductor industry introduces new generations of integrated circuits (IC) having higher performance and more functionality, the density of the elements forming the ICs increases, while the dimensions, sizes and spacing between components or elements are reduced. In the past, such reductions were limited only by the ability to define the structures photo-lithographically, device geometries having smaller dimensions created new limiting factors. For example, as the aspect ratio of conductive structures in the dielectric material in the back-end-of-line (BEOL) interconnect structure gets higher, electrical resistivity and resistive-capacitive (RC) delay increase. Therefore, improved methods of forming the interconnect structure are needed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a perspective view of a semiconductor device according to embodiments of present disclosure.

FIG. 2 is a cross-sectional view of an intermediate stage of manufacturing the semiconductor device structure, in accordance with some embodiments.

FIGS. 3A-3I are cross-sectional views of intermediate stages of manufacturing the interconnection structure, in accordance with some embodiments.

FIGS. 4A-4C are cross-sectional views of intermediate stages of manufacturing an interconnection structure, in accordance with some embodiments.

FIGS. 5A-5D are cross-sectional views of intermediate stages of manufacturing an interconnection structure, in accordance with some embodiments.

FIGS. 6A-6F are cross-sectional views of intermediate stages of manufacturing an interconnection structure, following some embodiments.

FIG. 7A-7G are cross-sectional views of intermediate stages of manufacturing an interconnection structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

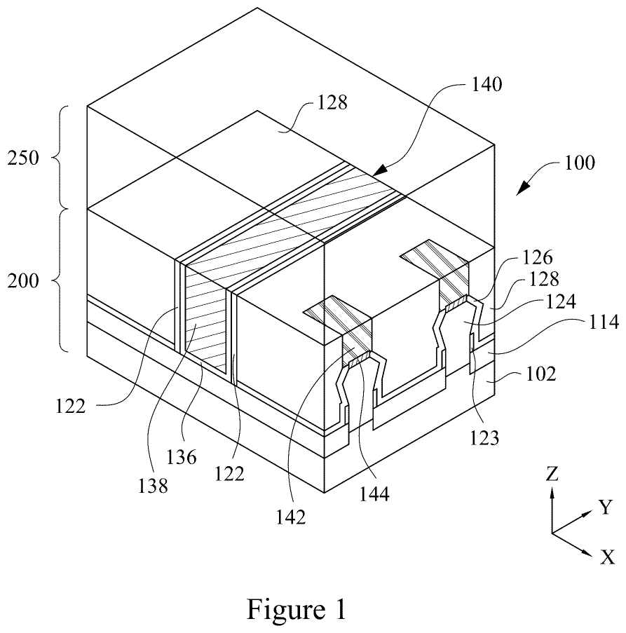

FIG. 1 is a perspective sectional view of a semiconductor device structure 100 including a device layer 200 and an interconnect structure 250. The device layer 200 includes a substrate 102 and one or more devices formed in or on the substrate 102. The substrate 102 may be a semiconductor substrate. In some embodiments, the substrate 102 includes a crystalline semiconductor layer on at least the surface of the substrate 102. The substrate 102 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb), and indium phosphide (InP). For example, the substrate 102 is made of Si. In some embodiments, the substrate 102 is a silicon-on-insulator (SOI) substrate, which includes an insulating layer (not shown) disposed between two silicon layers. In one aspect, the insulating layer is an oxygen-containing material, such as an oxide.

The substrate 102 may include various regions, including active regions and isolation regions. The active regions may be suitably doped with impurities (e.g., p-type or n-type impurities), for forming, for example, well regions.

As described above, the device layer 200 may include any suitable devices, such as transistors, diodes, imaging sensors, resistors, capacitors, inductors, memory cells, or a combination thereof. In some embodiments, the device layer 200 includes transistors, such as planar field effect transistors (FETs), FinFETs, nanostructure transistors, or other suitable transistors. The nanostructure transistors may include nanosheet transistors, nanowire transistors, gate-all-around (GAA) transistors, multi-bridge channel (MBC) transistors, or any transistors having the gate electrode surrounding the channels. An example of the device formed on the substrate 102 is a FinFET, which is shown in FIG. 1. The device layer 200 includes source/drain (S/D) regions 124 and gate stacks 140 (only one is shown in FIG. 1). Each gate stack 140 may be disposed between S/D regions 124 serving as source regions and S/D regions 124 serving as drain regions. For example, each gate stack 140 may extend along the Y-axis between one or more S/D regions 124 serving as source regions and one or more S/D regions 124 serving as drain regions. While not shown, channel regions are formed between the S/D regions 124 and have at least three surfaces wrapped around by the gate stack 140.

The S/D regions 124 may include a semiconductor material, such as Si or Ge, a III-V compound semiconductor, an II-VI compound semiconductor, or other suitable semiconductor material. Exemplary S/D region 124 may include, but are not limited to, Ge, SiGe, GaAs, AlGaAs, GaAsP, SiP, InAs, AlAs, InP, GaN, InGaAs, InAlAs, GaSb, AlP, GaP, and the like. The S/D regions 124 may include p-type dopants, such as boron; n-type dopants, such as phosphorus or arsenic; and/or other suitable dopants including combinations thereof. The S/D regions 124 may be formed by an epitaxial growth method using CVD, atomic layer deposition (ALD) or molecular beam epitaxy (MBE). The channel regions may include one or more semiconductor materials, such as Si, Ge, GeSn, SiGe, GaAs, InSb, GaP, GaSb, InAlAs, InGaAs, GaSbP, GaAsSb, GaN, or InP. The channel regions may include the same semiconductor material as the substrate 102. In some embodiments, the device layer 200 may include FinFETs, and the channel regions are a plurality of fins disposed below the gate stacks 140. In some embodiments, the device layer 200 may include nanostructure transistors, and the channel regions are surrounded by the gate stacks 140.

The gate stack 140 includes a gate electrode layer 138 disposed over the channel region (or surrounding the channel region for nanostructure transistors). The gate electrode layer 138 may be a metal-containing material such as tungsten, cobalt, aluminum, ruthenium, copper, multilayers thereof, or the like, and can be deposited by ALD, plasma enhanced chemical vapor deposition (PECVD), MBD, physical vapor deposition (PVD), or any suitable deposition technique. The gate stack 140 may further include a gate dielectric layer 136 disposed over the channel region. The gate electrode layer 138 may be disposed over the gate dielectric layer 136. In some embodiments, an interfacial layer (not shown) may be disposed between the channel region 108 and the gate dielectric layer 136, and one or more work function layers (not shown) may be formed between the gate dielectric layer 136 and the gate electrode layer 138. The interfacial dielectric layer may include a dielectric material, such as an oxygen-containing material or a nitrogen-containing material, or multilayers thereof, and may be formed by any suitable deposition method, such as CVD, PECVD, or ALD. The gate dielectric layer 136 may include a dielectric material such as an oxygen-containing material or a nitrogen-containing material, a high-k dielectric material having a k value greater than that of silicon dioxide, or multilayers thereof. The gate dielectric layer 136 may be formed by any suitable method, such as CVD, PECVD, or ALD. In some embodiments, the gate dielectric layer 136 may be a conformal layer. The term “conformal” may be used herein for ease of description upon a layer having substantial same thickness over various regions. The one or more work function layers may include aluminum titanium carbide, aluminum titanium oxide, aluminum titanium nitride, or the like.

Gate spacers 122 are formed along sidewalls of the gate stacks 140 (e.g., sidewalls of the gate dielectric layer 136). The gate spacers 122 may include silicon oxycarbide, silicon nitride, silicon oxynitride, silicon carbon nitride, the like, multi-layers thereof, or a combination thereof, and may be deposited by CVD, ALD, or other suitable deposition technique. In some embodiments, fin sidewall spacers 123 may be disposed on opposite sides of each S/D region 124, and the fin sidewall spacers 123 may include the same material as the gate spacers 122. Portions of the gate stacks 140, the gate spacers 122, and the fin sidewall spacers 123 may be disposed on isolation regions 114. The isolation regions 114 are disposed on the substrate 102. The isolation regions 114 may include an insulating material such as an oxygen-containing material, a nitrogen-containing material, or a combination thereof. In some embodiments, the isolation regions 114 are shallow trench isolation (STI). The insulating material may be formed by a high-density plasma chemical vapor deposition (HDP-CVD), a flowable chemical vapor deposition (FCVD), or other suitable deposition process. In one aspect, the isolation regions 114 includes silicon oxide that is formed by a FCVD process.

A contact etch stop layer (CESL) 126 is formed on the S/D regions 124 and the isolation region 114, and an interlayer dielectric (ILD) layer 128 is formed on the CESL 126. The CESL 126 can provide a mechanism to stop an etch process when forming openings in the ILD layer 128. The CESL 126 may be conformally deposited on surfaces of the S/D regions 124 and the isolation regions 114. The CESL 126 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be deposited by CVD, PECVD, ALD, or any suitable deposition technique. The ILD layer 128 may include an oxide formed by tetraethylorthosilicate (TEOS), un-doped silicate glass, or doped silicon oxide such as borophosphosilicate glass (BPSG), fused silica glass (FSG), phosphosilicate glass (PSG), boron doped silicon glass (BSG), organosilicate glass (OSG), SiOC, and/or any suitable low-k dielectric materials (e.g., a material having a dielectric constant lower than that of silicon dioxide), and may be deposited by spin-on, CVD, FCVD, PECVD, PVD, or any suitable deposition technique.

S/D contacts 142 may be disposed in the ILD layer 128 and over the S/D region 124. The S/D contacts 142 may be electrically conductive and include a material having one or more of Ru, Mo, Co, Ni, W, Ti, Ta, Cu, Al, TiN or TaN, and the conductive contact may be formed by any suitable method, such as electro-chemical plating (ECP), CVD, or PVD. A silicide layer 144 may be disposed between the S/D contacts 142 and the S/D region 124. The silicide layers 144 may be made of a metal or metal alloy silicide, and the metal includes a noble metal, a refractory metal, a rare earth metal, alloys thereof, or combinations thereof.

In integrated circuits, interconnection structures (or interconnect structures) are used to provide signal routing and power supply to semiconductor devices. An integrated circuit chip typically includes a device layer, fabricated during front-end-of-line (FEOL) and middle-end-of-line (MEOL) processes, and a back-end-of-line (BEOL) layer. The device layer may be formed in and/or on the substrate, and the BEOL layer is formed on a front side and/or backside of the device layer. The device layer may include various semiconductor devices, such as transistors, diodes, capacitors, resistors, etc., and may be formed in and/or on the substrate. In some embodiments, the device layer may also include the MEOL structures, such as one or more dielectric layers with conductive structures connected to gates and source/drain features in the device layer. Interconnection structures typically include conductive lines and vias formed in both the device layer and the BEOL layers.

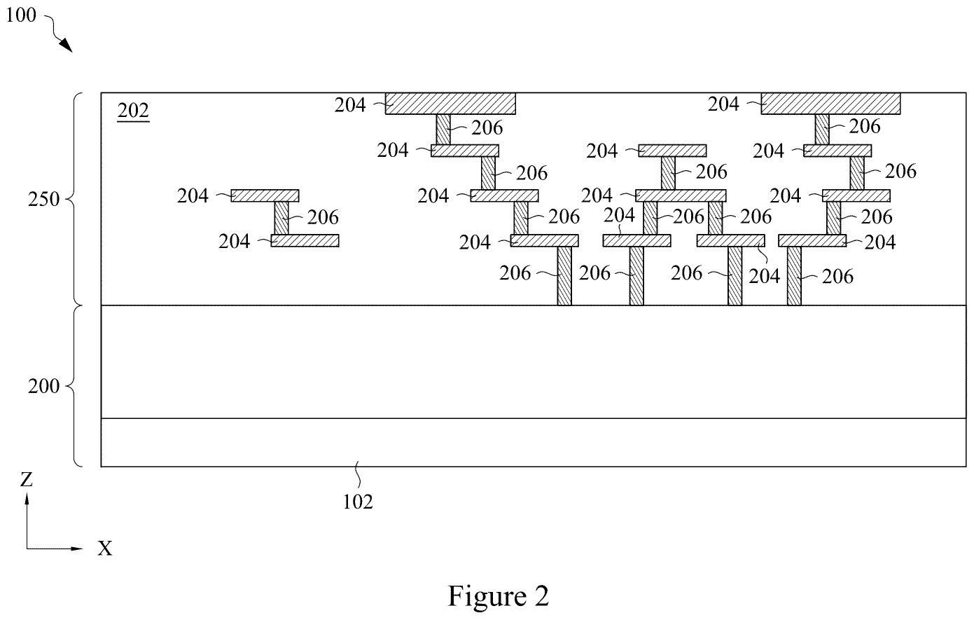

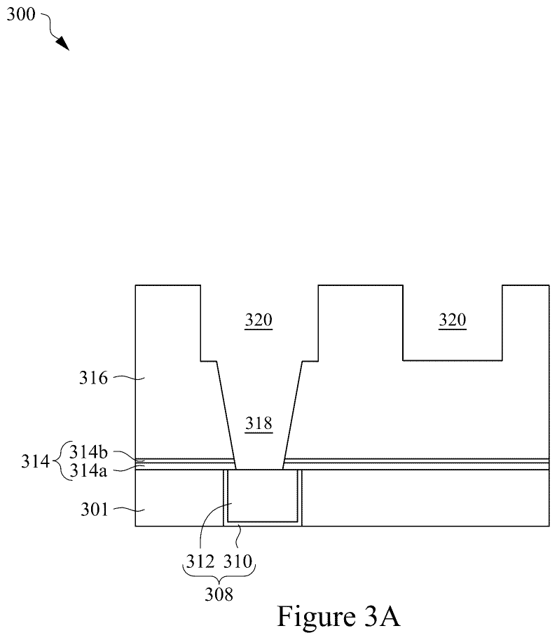

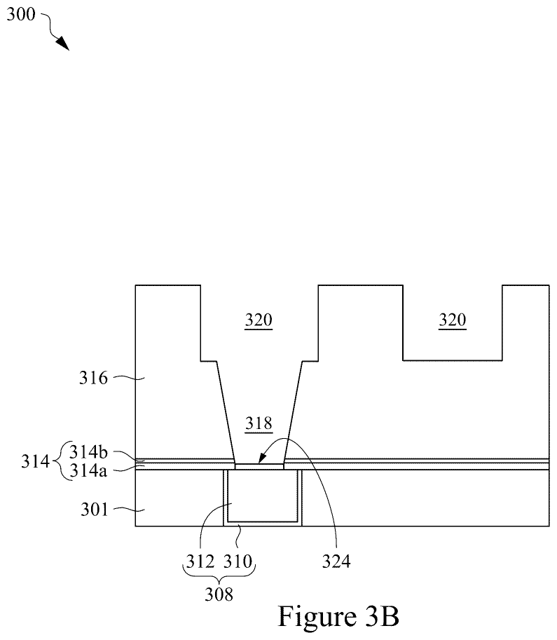

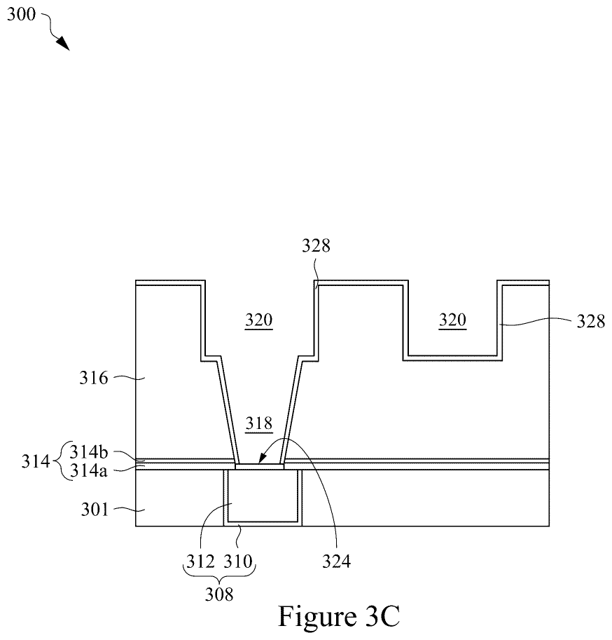

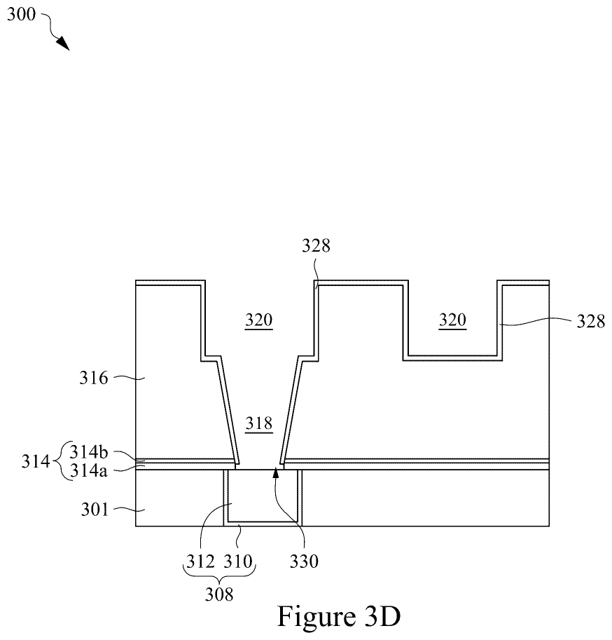

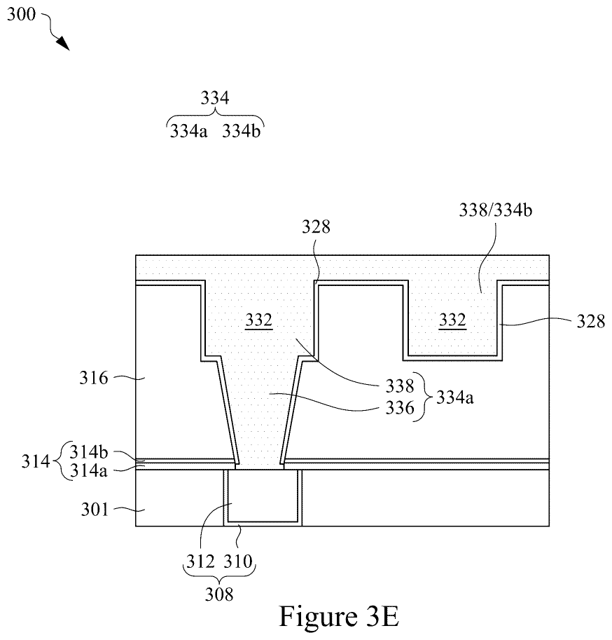

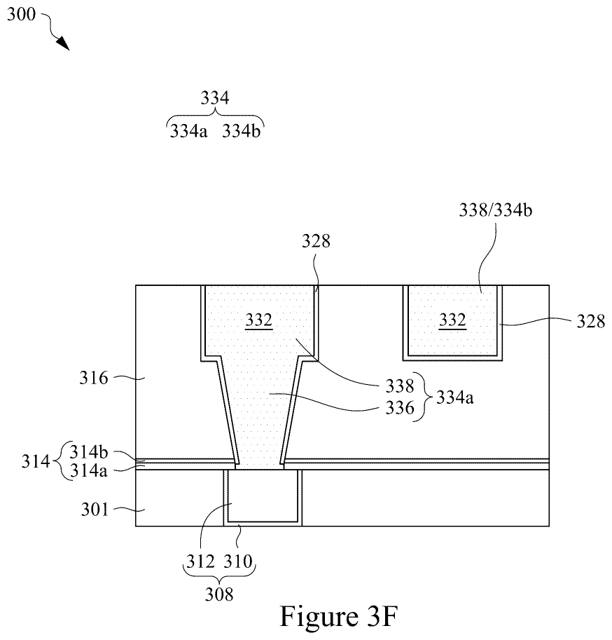

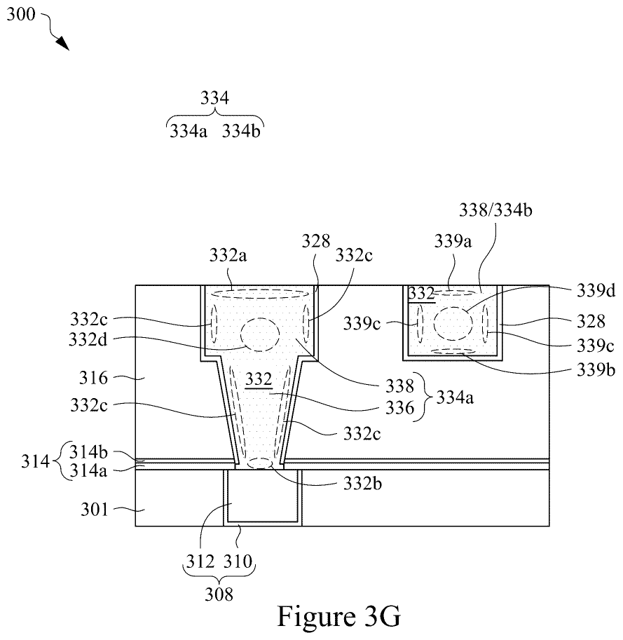

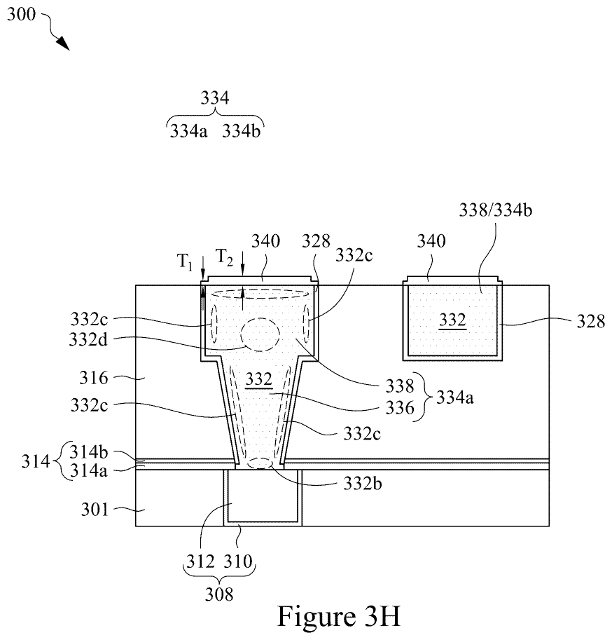

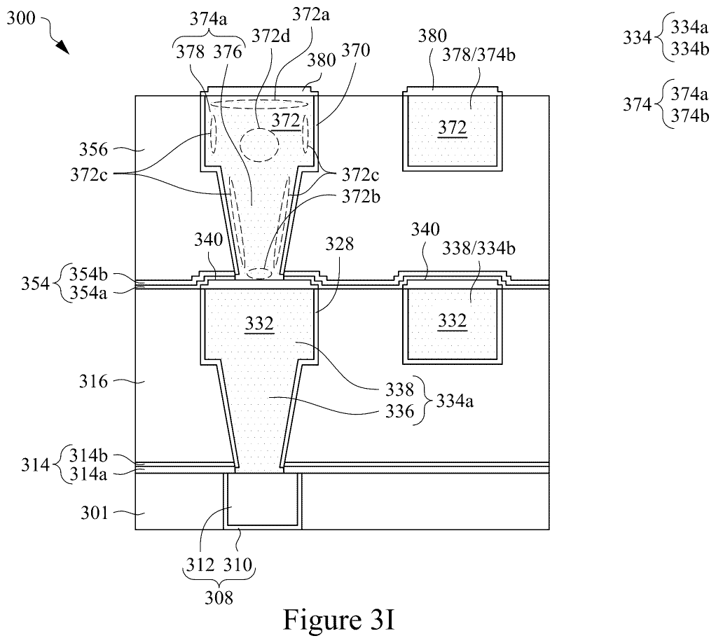

FIG. 2 is a cross-sectional view of an intermediate stage of manufacturing the semiconductor device structure 100, in accordance with some embodiments. The interconnect structure 250 is formed over the device layer 200. The interconnect structure 250 includes various conductive structures, such as conductive lines 204 and conductive vias 206, formed in a dielectric layer 202. The dielectric layer 202 may be an intermetal dielectric (IMD) layer or an interlayer dielectric (ILD) layer. The dielectric layer 202 may include multiple dielectric layers embedding multiple levels of conductive lines and vias 204, 206. The dielectric layer 202 includes a dielectric material, such as SiOₓ, SiOₓC_{y}H_{z}, or SiOₓC_{y}, where x, y and z are integers or non-integers. In some embodiments, the dielectric layer 202 includes a low-k dielectric material having a k value less than that of silicon oxide. The conductive lines 204 and conductive vias 206 may be made from one or more electrically conductive materials, such as metal, metal alloy, metal nitride, or silicide. The conductive vias 206 and lines 204 are arranged in levels to provide electrical paths to the gate electrode 138 (FIG. 1) and S/D contacts 142 (FIG. 1) in the device layer 200. In some embodiments, a backside interconnect structure (not shown), similar to the interconnect structure 250, may be formed on the backside of the device layer 200 to provide power supply and/or additional signal connection to the device layer 200. FIGS. 3A-7G to be discussed below relate to interconnection structures and methods of forming thereof, in accordance with some embodiments.

FIGS. 3A-3G are cross-sectional views of intermediate stages of manufacturing an interconnect structure 300, in accordance with some embodiments. The interconnect structure 300 may be one or more layers of the interconnect structure 250 shown in FIGS. 1 and 2. In FIG. 3A, the interconnect structure 300 includes a first dielectric layer 301, which may be an ILD layer or an IMD layer. For example, the first dielectric layer 301 may be the ILD layer 128 (FIG. 1) or the dielectric layer 202 (FIG. 2). The first dielectric layer 301 may include the same material as the ILD layer 128 or the dielectric layer 202. In some embodiments, the first dielectric layer 301 includes a low-k dielectric material, such as SiOCH. The first dielectric layer 301 may be formed by CVD, FCVD, ALD, spin coating, or other suitable process. One or more first conductive structure 308 may be disposed in the first dielectric layer 301. The one or more first conductive structure 308 may be electrically connected to the S/D regions 124 (FIG. 1) and/or the gate electrode layer 138 (FIG. 1). In some embodiments, the first conductive structure 308 is the conductive lines 204 and/or conductive vias 206 shown in FIG. 2. The first conductive structure 308 may include a first barrier layer 310 and a first main conductive layer 312 over the first barrier layer 310. The first barrier layer 310 may include metal nitride, metal oxide, or a combination thereof. Suitable metals for the first barrier layer 310 may include, but are not limited to, Ta, Ti, W, or In. In some embodiments, the first barrier layer 310 is a metal nitride, such as TaNx, TiNx or WNx. The first barrier layer 310 may prevent the metal diffusion from the first main conductive layer 312 to the first dielectric layer 301. The first main conductive layer 312 may include a metal material having a low resistance, such as Cu, Co, Ag, Au, Al, W, Zn, alloys thereof, or combinations thereof.

As shown in FIG. 3A, an etch stop layer 314 and a second dielectric layer 316 are formed over the first dielectric layer 301. The second dielectric layer 316 may be the dielectric layer 202 (FIG. 2). The etch stop layer 314 may include a material different from the second dielectric layer 316 to have different etch selectivity compared to the second dielectric layer 316. In some embodiments, the etch stop layer 314 is made of a dielectric material, such as an oxide, a nitride, a metal oxide, a metal nitride, or a combination thereof. Suitable materials for the etch stop layer 314 may include, but not limited to, silicon nitride, silicon carbide, oxygen-doped silicon carbide (ODC), silicon carbon nitride, silicon oxynitride, carbon nitride, silicon oxide, silicon carbon oxide, and aluminum oxide, etc. The etch stop layer 314 may be a single layer or a multi-layer structure including a plurality of layers having different materials. In some embodiments, the etch stop layer 314 includes a first layer 314a in contact with the first dielectric layer 301 and a second layer 314b disposed on the first layer 314a. The first layer 314a and the second layer 314b may include different materials. In some embodiments, the first layer 314a and the second layer 314b are the same material but with different compositions. In one exemplary embodiment shown in FIG. 3A, the first layer 314a includes aluminum oxide, and the second layer 314b includes silicon carbide. Although only two layers are shown in FIG. 3A, the etch stop layer 314 may include more layers. The etch stop layer 314 may be formed by any suitable process, such as CVD, ALD, PVD, PEALD, or PECVD.

The second dielectric layer 316 may include a same material as the first dielectric layer 301 and may be formed by processes similar to those of the first dielectric layer 301. In some embodiments, openings 318 and 320 are formed in and through the second dielectric layer 316, as shown in FIG. 3A. The openings 318 and 320 may be formed by any suitable process, such as one or more etch processes. In some embodiments, the openings 318 and 320 are a result of a dual-damascene process. The openings 320 may be trenches opening formed in an upper portion of the second dielectric layer 316. The opening 318 may be a via opening formed through the second dielectric layer 316 and the etch stop layer 314 to expose a portion of the first conductive structure 308 to the opening 320. As illustrated in FIG. 3A, the opening 318 may expose the first main conductive layer 312 but does not expose the first barrier layer 310. In some embodiments, the opening 318 exposes both the first main conductive layer 312 and the first barrier layer 310.

In FIG. 3B, a blocking layer 324 is selectively formed on the exposed top surface of the first conductive structure 308. The blocking layer 324 may be organic material including small molecules or polymer. In some embodiments, the blocking layer 324 may include one or more self-assembled monolayers (SAMs) having a head group and a tail group. The head group of the SAM may be selected depending on the material of the first conductive structure 308. In some embodiments, the head group of the SAM may include a phosphorus (P), sulfur (S), silicon (Si), or nitrogen (N) terminated compound which may only attach to the metallic surfaces, such as the exposed top surface of the first conductive structure 308. For example, the head group of the SAM may include an azole group-containing compound when Cu or Co is used for the first conductive structure 308. The head group of the SAM may not form on the dielectric surface of the second dielectric layer 316 and the etch stop layer 314. The tail group of the SAM may include a highly hydrophobic long alkyl chain which blocks adsorption of a precursor (e.g., precursor for forming the subsequent second barrier layer 328) from forming on the blocking layer 324. In some embodiments, the tail group includes a polymer such as polyimide. The blocking layer 324 may be formed by supplying a blocking agent to the exposed surfaces, for example by CVD, ALD, molecular layer deposition (MLD), wet coating, immersion process, or other suitable methods.

In some embodiments, the blocking layer 324 is formed by a wet-coating process, and the solution for wet coating may be a protic organic solvent such as alcohols, carboxylic acids, or a combination thereof. Exemplary protic organic solvents may include, but are not limited to, methanol, ethanol, 1-propanol, 2-propanol, 1-butanol, 1-pentanol, 1-hexanol, 1-heptanol, 2-ethoxyethanol, and mixtures thereof. The solution for wet coating may also be a polar or nonpolar protic solvent. Exemplary polar aprotic solvents may include, but are not limited to, N,N-dimethylformamide, N-methyl-2-pyrrolidinone, acetonitrile, acetone, ethyl acetate, benzyl ether, trioctylphosphine, trioctylphosphine oxide, and mixtures thereof. Exemplary nonpolar protic solvents may include, but are not limited to, alkane, olefin, an aromatic, an ester or an ether solvent, hexane, octane, benzene, toluene, xylene, and mixtures thereof. It is contemplated that the wet-coating process herein is applicable to formation of other blocking layer discussed in this disclosure. In some embodiments, the blocking layer 324 has a thickness less than the first layer 314a of the etch stop layer 314, or less than the total thickness of the etch stop layer 314. In some embodiments, the blocking layer 324 has a thickness greater than the total thickness of the etch stop layer 314.

In FIG. 3C, a second barrier layer 328 is deposited over dielectric surfaces, such as over the second dielectric layer 316 and the etch stop layer 314, in accordance with some embodiments. The second barrier layer 328 may be a material that is capable of sufficiently preventing metal diffusion from the main conductive materials (e.g., second main conductive layer 332, FIG. 3E) to other layers (e.g., the second dielectric layer 316) in a limited thickness. In some embodiments, the second barrier layer 328 includes a metal layer formed of Ru, Mo, or the like. For example, the second barrier layer 328 may be a single continuous layer of Ru or Mo. In some embodiments, the second barrier layer 328 also includes conductive grains (not shown in figures) which are not thick enough to form a continuous layer and embedded in the continuous layer formed of Ru or Mo. For example, the second barrier layer 328 may include the conductive grains firstly formed on the surfaces of the second dielectric layer 316 and the etch stop layer 314 and the continuous layer of Ru or Mo are then formed covering the conductive grains. In some embodiments, the conductive grains are a material similar to the first barrier layer 310, such as TiNx, TaNx, WNx, or a combination thereof. The conductive grains may help the continuous layer of Ru or Mo to have a better growth quality. In some embodiments, the conductive grains and the second barrier layer 328 include different materials. In some embodiments, the second barrier layer 328 has a total thickness ranging from about 1.5 nm to about 3 nm for advanced interconnects, although the second barrier layer 328 may have a thickness greater than 3 nm, in accordance with some embodiments. In some embodiments that conductive segments or dots are used, the conductive grains have a thickness less than about 1.5 nm, and the continuous layer of Ru or Mo has a thickness of over about 1.5 nm.

With the blocking layer 324 being formed on the metallic top surfaces of the first conductive structure 308, the second barrier layer 328 is selectively formed over the second dielectric layer 316 and the etch stop layer 314 and not formed on the blocking layer 324. The selective deposition of the second barrier layer 328 is achieved through the use of the blocking layer 324. For example, the blocking layer 324 may block the second barrier layer 328 from forming on the metallic surface of the first conductive structure 308. Specifically, the blocking layer 324 blocks the precursor(s) of the second barrier layer 328 from forming thereon, so the precursor(s) of the second barrier layer 328 grows on the dielectric surfaces, such as the surfaces of the second dielectric layer 316 and the etch stop layer 314. The selective deposition of the second barrier layer 328 can also be achieved and/or enhanced through the use of ALD process and/or MLD process so that the second barrier layer 328 has the characteristic or property of being specific in bonding with the second dielectric layer 316 and the etch stop layer 314 through self-limiting surface reactions.

In FIG. 3D, after the formation of the second barrier layer 328, the blocking layer 324 is removed to expose the top surface of the first conductive structure 308. The blocking layer 324 may be removed using thermal degradation or plasma bombardment, or other suitable process. The removal process does not substantially affect the second barrier layer 328. With the removal of the blocking layer 324, a vertical gap 330 between the second barrier layer 328 and the top surface of the first conductive structure 308 may be formed. Depending on the thickness of the blocking layer 324, the vertical gap 330 may be less than the thickness of the first layer 314a, less than the total thickness of the etch stop layer 314, or greater than the total thickness of the etch stop layer 314. In some embodiments, the vertical gap 330 is small and can be negligible. In some embodiments, the blocking layer 324 have residues left on the top surface of the first conductive feature 308, such that phosphorus, sulfur, silicon, nitrogen, or a combination thereof may be found in a top portion of the first conductive feature 308.

In FIG. 3E, a second main conductive layer 332 is filled in the opening 318 and openings 320 to form second conductive structures 334 together with the second barrier layer 328, in accordance with some embodiments. Specifically, the second conductive structure 334 may include one or more first damascene structures 334a that includes a conductive via 336 in the opening 318 and a conductive line 338 in the opening 320 and/or one or more second damascene structure 334b that includes the conductive line 338 only. In other words, the second barrier layer 328 and the second main conductive layer 332 in the opening 318 may form the conductive via 336, and the second barrier layer 328 and the second main conductive layer 332 in the openings 320 may form the conductive lines 338. The first damascene structure 334a is physically and electrically connected to the underlying first conductive structure 308.

In some embodiments. the second main conductive layer 332 includes a low-resistance bulk material doped with a metal dopant. For example, the low-resistance bulk material of the second main conductive layer 332 may be Cu, Co, Ag, Au, Al, W, Zn, alloys thereof. The metal dopant may be Mn, Ti, Co, Al, Zn, In, a combination thereof, or other suitable material that can improve the miscibility between the second barrier layer 328 and the bulk material of the second main conductive layer 332. The improved miscibility between the second barrier layer 328 and the bulk material of the second main conductive layer 332 can reduce or prevent the second barrier layer 328 being agglomerated as well as reduce or prevent the second main conductive layer 332 being peeled off from the second barrier layer 328, thereby improving the thermal stability and reliability of the interconnect structure 300. In some embodiments, the second main conductive layer 332 has about 0.5 at % to about 5 at % of the metal dopant. Too less the metal dopant in the second main conductive layer 332 may not sufficiently improve the miscibility between the second barrier layer 328 and the second main conductive layer 332, and too much the metal dopant in the second main conductive layer 332 may affect the conductivity of the second main conductive layer 332. With having the metal dopant in the second main conductive layer 332, the second barrier layer 328 can be very thin, such as thin as to about 1.5 nm, while providing the same barrier performance as a thick TaN or TiN layer (thickness greater than about 3 nm), and the conductive line 338 having a fine pitch (e.g., less than about 10 nm) can thus have a sufficient volume to contain the low-resistance bulk material of the second main conductive layer 332. Thus, the conductive lines 338 having the fine pitch can have a reduced resistance with the use of the second barrier layer 328 and the metal dopant.

In some embodiments, the second main conductive layer 332 is formed by PVD, such as by sputtering a target comprising the desired chemical composition for the second main conductive layer 332. For example, for forming the second main conductive layer 332 formed of 99 at % of Cu and 1 at % of Mn, a target comprising 99 at % of Cu and 1 at % of Mn may be used. In FIG. 3E, the second main conductive layer 332, as deposited, may have the metal dopant uniformly distributed through the second main conductive layer 332. The second main conductive layer 332 may have a height over the top of the second dielectric layer 316, such as including excess portions extending over an upper surface of the second dielectric layer 316. As will be described in detail below, the metal dopant in the second main conductive layer 332 may diffuse toward surfaces or edges of the second main conductive layer 332 by an anneal process, which allows the second main conductive layer 332 to effectively improve the miscibility with the second barrier layer 328 by doping a low concentration of the metal dopant.

In some embodiments, the second main conductive layer 332 may extend into the vertical gap 330, such as extending below the bottom of the second barrier layer 328. The second main conductive layer 332 may completely or partially fill the vertical gap 330 (FIG. 3D). In embodiments that the second main conductive layer 332 completely fills the vertical gap 330, the second main conductive layer 332 is in physical contact with the etch stop layer 314. In embodiments that the second main conductive layer 332 partially fills the vertical gap 330, air gap (not shown) may be formed, such as air gaps being enclosed by the second main conductive layer 332, the second barrier layer 328, the etch stop layer 314, and the first conductive structure 308.

In FIG. 3F, a planarization process, such as chemical mechanical planarization (CMP) process, may then be performed to remove excess portions of the second barrier layer 328 and the second main conductive layer 332. After the planarization process, the conductive lines 338 may have an upper surface level with an upper surface of the second dielectric layer 316 and an upper surface the second barrier layer 328.

In FIG. 3G, an anneal process is performed on the interconnect structure 300, in accordance with some embodiments. The anneal process may be performed at a temperature of about 300 degrees Celsius to about 400 degrees Celsius with H₂ or other suitable gases, at a pressure of about 5 torr to about 760 torr with an anneal time from about 1 min to about 10 min. The metal dopant in the second main conductive layer 332 may diffuse toward the edges of the second main conductive layer 332 during the anneal process. For example, after the anneal process, the edge portions of the second main conductive layer 332 may have a metal dopant concentration higher than that in a center portion of the second main conductive layer 332. In some embodiments, after the anneal process, in the first damascene structure 334a, the second main conductive layer 332 includes a first portion 332a near the upper edge of the second main conductive layer 332, a second portion 332b near a lower edge of the second main conductive layer 332 (e.g., near the first conductive structure 308), third portions 332c near sidewalls of the second barrier layer 328, and a center portion 332d of the second main conductive layer 332 between the first portion 332a, the second portion 332b, and the third portions of the second main conductive layer 332. In the first damascene structure 334a, the center portion 334d of the second main conductive layer 332 may have a metal dopant concentration lower than that in the first portion 332a, the second portion 332b, and third portions 332c of the second main conductive layer 332. In some embodiments, the metal dopant also diffuses into the first main conductive layer 312, such as diffusing to a level lower than an upper surface of the first dielectric layer 301 and a bottom surface of the etch stop layer 314 from the first damascene structure 334a. As a result, second portion 332b of the second main conductive layer 332 may have a metal dopant concentration lower than that in the first portion 332a and third portions 332c of the second main conductive layer 332.

In some embodiments, after the anneal process, in the second damascene structure 334b, the second main conductive layer 332 includes a first portion 339a near the upper edge of the second main conductive layer 332, a second portion 339b near a lower edge of the second main conductive layer 332, third portions 339c near sidewalls of the second barrier layer 328, and a center portion 339d of the second main conductive layer 332 between the first portion 339a, the second portion 339b, and the third portions 339c of the second main conductive layer 332. In the second damascene structure 334b, the center portion 339d of the second main conductive layer 332 may have a metal dopant concentration lower than that in the first portion 339a, the second portion 339b, and the third portions 339c of the second main conductive layer 332 after the anneal process. In some embodiments, in the second damascene structure 334b, the first portion 339a and the second portion 339b have substantially the same metal dopant concentration.

In some embodiments, a portion of the second main conductive layer 332 in the vertical gap 330 (FIG. 3D) also has a high concentration of the metal dopant after the anneal process. For example, the portion of the second main conductive layer 332 may have a concentration of the metal dopant greater than that in the center portion of the second main conductive layer 332. The high concentration of the metal dopant may help reduce the diffusion of the bulk material of the second main conductive layer 332 into the etch stop layer 314.

In FIG. 3H, a barrier cap 340 is selectively formed on the exposed surface of the second conductive structure 334, in accordance with some embodiments. The barrier cap 340 may be a material same as the second barrier layer 328 although the barrier cap 340 may include materials different from the second barrier layer 328. For example, the barrier cap 340 includes Ru or Mo, such as a capping layer formed of Ru or Mo. The barrier cap 340 may be selectively deposited on the metallic surfaces, such as on the exposed portions of conductive lines 338 and the second barrier layer 328. In some embodiments, the barrier cap 340 does not extend onto the second dielectric layer 316, or only has a negligible portion extending onto the second dielectric layer 316.

The selective deposition of the barrier cap 340 can be achieved and/or enhanced through the use of ALD process and/or MLD process so that the barrier cap 340 has the characteristic or property of being specific in bonding with the conductive lines 338 and the second barrier layer 328 through self-limiting surface reactions. Alternatively, a mask (not shown) may be used to block the barrier cap 340 being formed on the top surface of the second dielectric layer 316. The mask may include a material similar to those of the blocking layer 324 and may be formed by processes similar to those of the blocking layer 324. The mask may be removed using, such as thermal degradation or plasma bombardment, or other suitable process, after the barrier cap 340 is formed.

The deposition of barrier cap 340 have different deposition rates on the second barrier layer 328 and the conductive lines 338, in accordance with some embodiments. For example, precursors of the barrier cap 340 (e.g., cyclopentadienyl dicarbonyl cobalt [CpCo(CO)₂]) generally may prefer to nucleate on pure metal (e.g., Cu, Co, Ta) than metal compounds (e.g., CuO, CoO, TaN). For example, depending on the selection of deposition chemicals, the deposition of barrier cap 340 may have a first deposition rate on the second barrier layer 328 and a second deposition rate on the conductive lines 338, and the second deposition rate is greater than the first deposition rate. As a result, the barrier cap 340 may have a first thickness T₁ on the second barrier layer 328 and a second thickness T₂ on the conductive lines 338, and the second thickness T₂ is greater than the first thickness T₁. In some embodiments, the first thickness T₁ ranges from about 0.5 nm to about 2 nm, and the second thickness T2 ranges from about 2 nm to about 5 nm. While the barrier cap 340 includes a sufficient second thickness T₂ on the conductive lines 338 to prevent the material of the conductive lines 338 from diffusing out, a thin first thickness T₁ at side edges of the barrier cap 340 can allow the subsequently formed dielectric layers (e.g., etch stop layer 354 and third dielectric layer 356, FIG. 3I) to have a better step coverage on the side edges of the barrier cap 340.

In FIG. 3I, the processes for forming the second dielectric layer 316 and the second conductive structures 334, including the processes illustrated in FIGS. 3A-3H, are repeated and therefore form an upper-level interconnect structure over the second conductive structures 334 and the second dielectric layer 316, in accordance with some embodiments. The upper-level interconnect structure may include one or more third conductive structures 374 disposed in an etch stop layer 354 and a third dielectric layer 356. The etch stop layer 354 and the third dielectric layer 356 may include materials similar to those of the etch stop layer 314 and the second dielectric layer 316 and may be formed by processes similar to those of etch stop layer 314 and the second dielectric layer 316, respectively. In some embodiments, the third conductive structure 374 includes a first damascene structure 374a and a second damascene structure 374b. The first damascene structure 374a may include a conductive via 376 and a conductive line 378 connected to and over the conductive via 376, and the second damascene structure 374b may include the conductive line 378 only. The conductive via 376 and the conductive line 378 each includes a portion of the third barrier layer 370 and a portion of the third main conductive layer 372. In some embodiments, the third barrier layer 370 and the third main conductive layer 372 are formed of the material similar to those of the second barrier layer 328 and the second main conductive layer 332, respectively.

In some embodiments, because the diffusion of metal dopant is blocked by the barrier cap 340, an upper edge portion 372a, a lower edge portion 372b, and side edge portions 372c of the third main conductive layer 372 in the first damascene structure 374a have a similar metal dopant concentration, and which is greater than the metal dopant concentration in a center portion 372d of the third main conductive layer 372 in the first damascene structure 374a. In addition, the second damascene structure 374b of the third conductive structure 374 may have a metal dopant concentration profile similar to those in the second damascene structure 334b of the second conductive structure 334. In some embodiments, a barrier cap 380 is formed on the third barrier layer 370 and the conductive lines 378. The barrier cap 380 may have a thickness on the conductive lines 378 greater than a thickness on the third barrier layer 370.

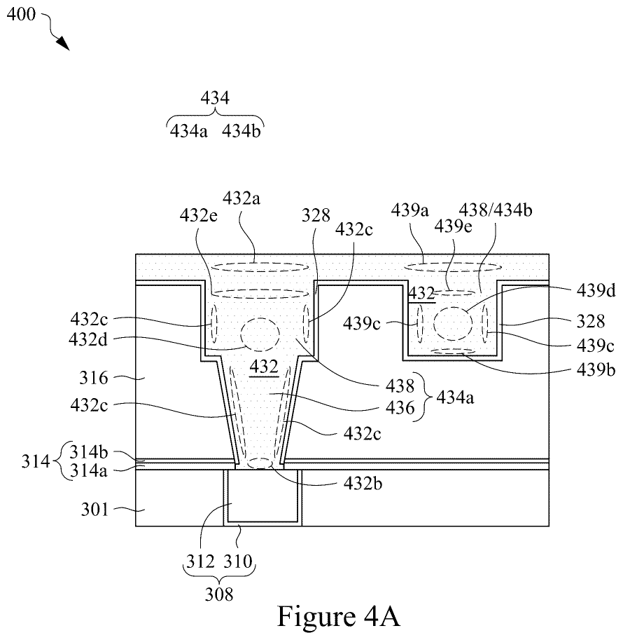

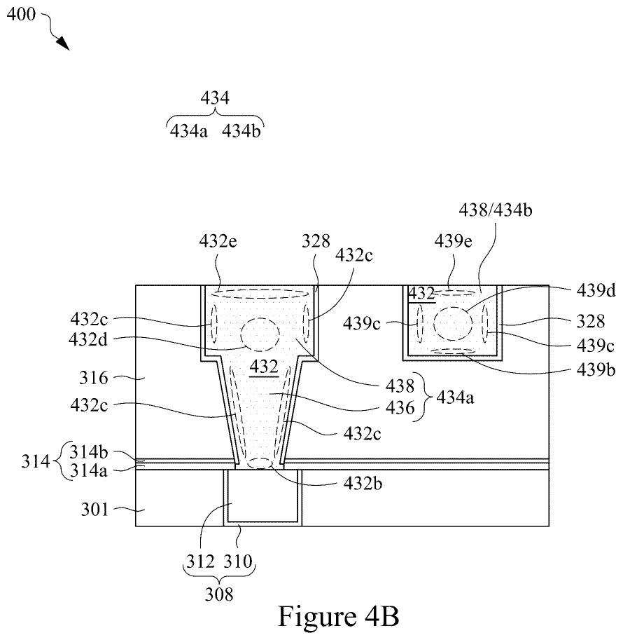

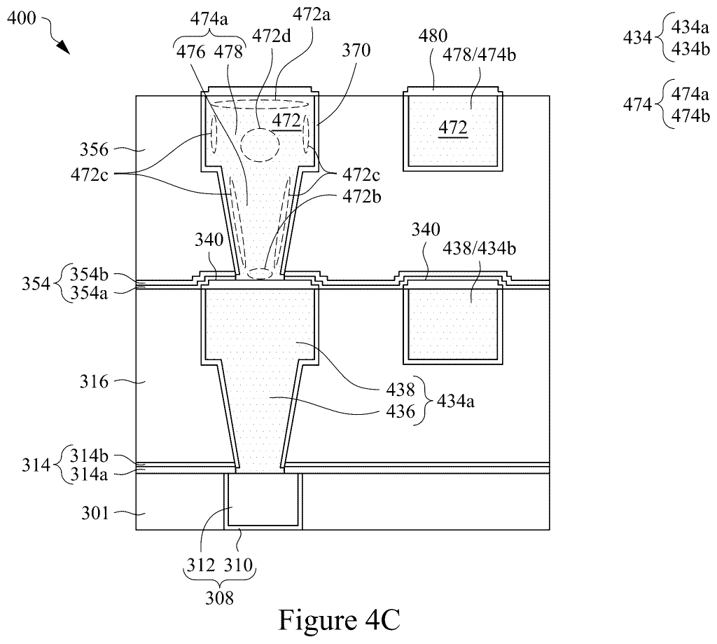

FIGS. 4A-4C are cross-sectional views of intermediate stages of manufacturing an interconnect structure 400, in accordance with some embodiments. Various embodiments of the interconnect structure 400 may be used to form one or more layers of the interconnect structure 250 shown in FIGS. 1 and 2. The interconnect structure 400 is similar to the interconnect structure 300, wherein like reference numerals refer to like element. In some embodiments illustrated in FIGS. 4A-4C, an anneal process for driving the diffusion of metal dopant is performed before the planarization process. For example, processing of manufacturing the interconnect structure 400 as illustrated in FIGS. 4A-4C assumes the processing illustrated in FIG. 3E performed prior. Accordingly, after the processing discussed above with reference to FIGS. 3A to 3E, processing may proceed to FIG. 4A.

In FIG. 4A, second conductive structures 434 in the second dielectric layer 316 are formed, in accordance with some embodiments. For example, the second conductive structures 434 may include a first damascene structure 434a and a second damascene structure 434b. The first damascene structure 434a may include a conductive via 436 and a conductive line 438 connected to and over the conductive via 436, and the second damascene structure 434b may include the conductive line 438 only. The conductive via 436 and the conductive line 438 may each include a portion of the second barrier layer 328 and a portion of the second main conductive layer 432 disposed over the second barrier layer 328. The second main conductive layer 432 may include a material similar to those of the second main conductive layer 332 and can be formed by processes similar to those of the second main conductive layer 332. As shown in FIG. 4A, the second barrier layer 328 and the second main conductive layer 432 have excess portions over an upper surface of the second dielectric layer 316, in accordance with some embodiments.

An anneal process is performed to drive the metal dopants to diffuse toward the edges of the second main conductive layer 432. The anneal process may be performed at a temperature of about 300 degrees Celsius to about 400 degrees Celsius with H₂ or other suitable gases, at a pressure of about 5 torr to about 760 torr with an anneal time from about 1 min to about 10 min. For example, after the anneal process, edge portions of the second main conductive layer 432 may have a higher metal dopant concentration than that in a center portion of the second main conductive layer 432. In some embodiments, after the anneal process, in the first damascene structure 434a, the second main conductive layer 432 includes a first portion 432a near the upper edge of the second main conductive layer 432, a second portion 432b near lower edge of the second main conductive layer 332 (e.g., near the first conductive structure 308), third portions 432c near sidewalls of the second barrier layer 328, and a center portion 432d of the second main conductive layer 432 between the first portion 432a, the second portion 432b, and the third portions 432c of the second main conductive layer 432. In the first damascene structure 434a, the center portion 432d of the second main conductive layer 432 may have a metal dopant concentration lower than that in the first portion 432a, the second portion 432b, and third portions 432c of the second main conductive layer 332. In some embodiments, the metal dopant also diffuses into the first main conductive layer 310, such as diffusing to a level lower than an upper surface of the first dielectric layer 301 and a bottom surface of the etch stop layer 314. As a result, in some embodiments, the metal dopant concentration in the second portion 432b of the second main conductive layer 432 is lower than that in the first portion 432a and third portions 432c of the second main conductive layer 432. In some embodiments, the second main conductive layer 432 further includes a fourth portion 432e below an upper surface of the second dielectric layer 316 and between the first portion 432a and the center portion 432d. In some embodiments, the fourth portion 432e of the second conductive structure 432d has a metal dopant concentration lower than the first portion 432a and the second portion 432b of the second main conductive layer 432 and greater than the center portion 432d of the second main conductive layer 432.

In some embodiments, after the anneal process, in the second damascene structure 434b, the second main conductive layer 432 includes a first portion 439a near the upper edge of the second main conductive layer 432, a second portion 439b near a lower edge of the second main conductive layer 432, third portions 439c near sidewalls of the second barrier layer 328, and a center portion 439d of the second main conductive layer 432 between the first portion 439a, the second portion 439b, and the third portions 439c of the second main conductive layer 332. In some embodiments, in the second damascene structure 434b, the second main conductive layer 432 further includes a fourth portion 439e below an upper surface of the second dielectric layer 316 and between the first portion 439a and the center portion 439d, and the fourth portion 439e of the second main conductive layer 432 has a metal dopant concentration lower than the first portion 439a, the second portion 439b, and the third portions 439c of the second main conductive layer 432. In the second damascene structure 434b, the center portion 439d of the second main conductive layer 432 may have a metal dopant concentration lower than that in the first portion 439a, the second portion 439b, third portions 439c, and the fourth portion 439e of the second main conductive layer 432.

In FIG. 4B, a planarization process, such as chemical mechanical planarization (CMP) process, may then be performed to remove excess portions of the second main conductive layer 432 and the second barrier layer 328. After the planarization process, the first portion 432a of the second main conductive layer 432 in the first damascene structure 434a and the first portion 439a of the second main conductive layer 432 in the second damascene structure 434b are removed. The conductive lines 438 may have an upper surface level with an upper surface of the second dielectric layer 316 and an upper surface of the second barrier layer 328.

In FIG. 4C, the processes for forming the second dielectric layer 316 and the second conductive structures 434, including the processes illustrated in FIGS. 3A-3E and FIGS. 4A-4B, are repeated and therefore form an upper-level interconnect structure over the second conductive structures 434 and the second dielectric layer 316, in accordance with embodiments. The upper-level interconnect structure may include third conductive structures 474 disposed in an etch stop layer 354 and a third dielectric layer 356. In some embodiments, the third conductive structure 474 may include a first damascene structure 474a and a second damascene structure 474b. The first damascene structure 474a may include a conductive via 476 and a conductive line 478 connected to and over the conductive via 476, and the second damascene structure 474b may include the conductive line 478 only. The conductive via 476 and the conductive line 478 may each include a portion of third barrier layer 370 and a portion of the third main conductive layer 472. The third main conductive layer 472 may be formed of a material similar to those of the second main conductive layer 432.

In some embodiments, because the diffusion of metal dopant is blocked by the barrier capping 340, in the first damascene structure 474a, a lower edge portion 472b and side edge portions 472c of the third main conductive layer 472 may have substantially the same metal dopant concentration, and which is greater than the metal dopant concentration in a center portion 472d of the third main conductive layer 372. In some embodiments, in the first damascene structure 474a, the upper edge portion 472e of the third main conductive layer 472 has a metal dopant concentration greater than that in the center portion 472d of the third main conductive layer 472 and lower than that in the lower edge portion 472b and the side edge portions 472c.

In the second damascene structure 474b of the third conductive structure 374 may have a metal dopant concentration profile similar to those in the second damascene structure 334b of the second conductive structure 334. In some embodiments, barrier cap 380 is formed on the third barrier layer 370 and the conductive lines 478 of the first damascene structure 474a and the second damascene structure 474b, and the barrier cap 380 may have a thickness on the conductive lines 478 greater than a thickness on the third barrier layer 370.

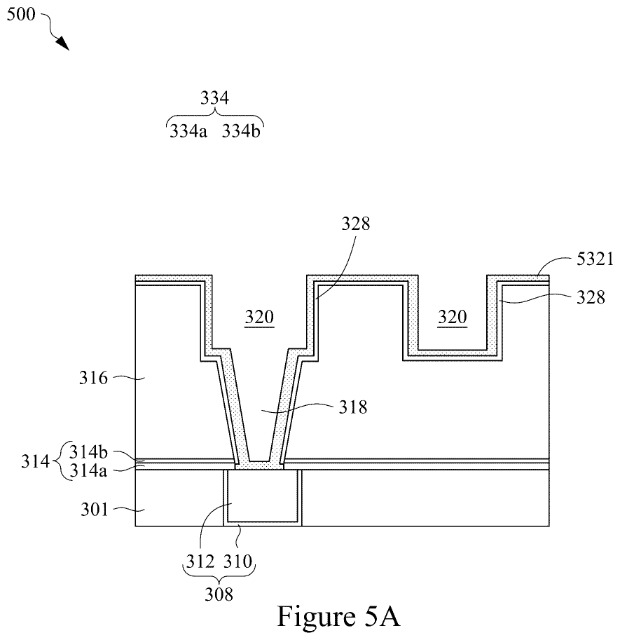

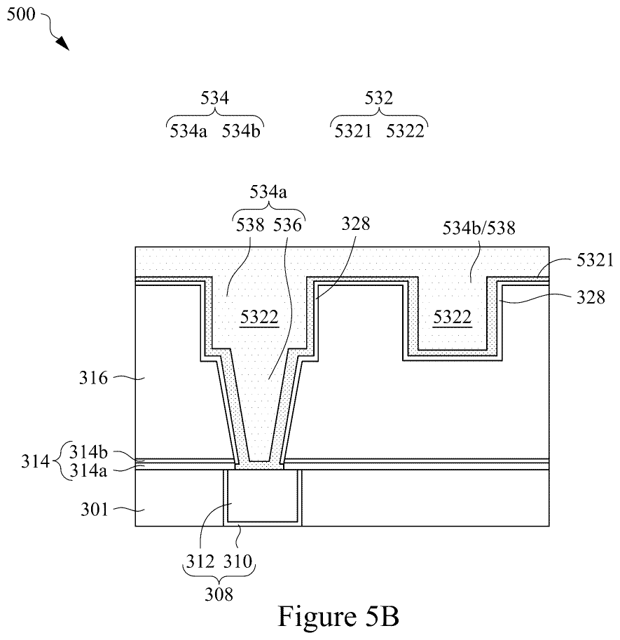

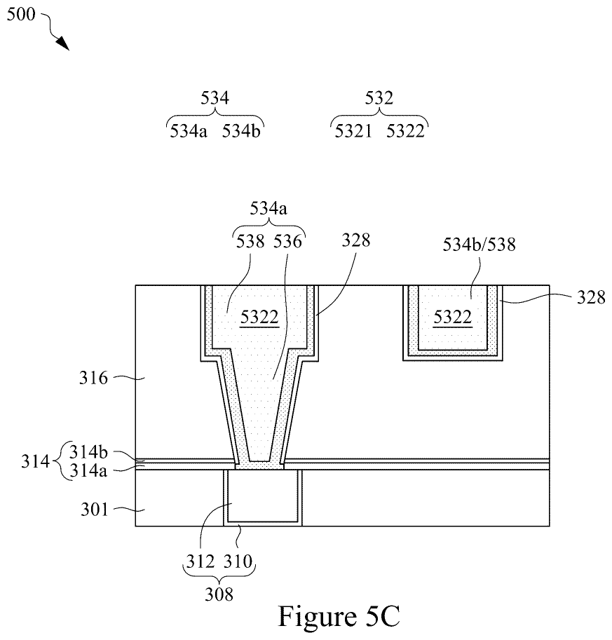

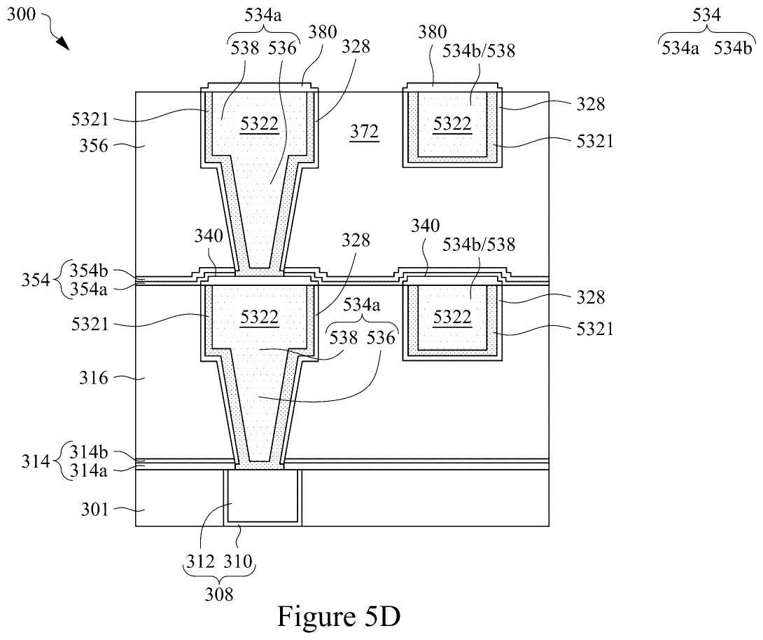

FIGS. 5A-5D are cross-sectional views of intermediate stages of manufacturing an interconnect structure 500, in accordance with some embodiments. Various embodiments of the interconnect structure 500 may be used to form one or more layers of the interconnect structure 250 shown in FIGS. 1 and 2. The interconnect structure 500 is similar to the interconnect structure 300 or 400, wherein like reference numerals refer to like element. In some embodiments illustrated in FIGS. 5A-5D, the second main conductive layer may include an first sub-layer having a high metal dopant concentration. For example, processing of manufacturing the interconnect structure 500 as illustrated in FIGS. 5A-5D assumes the processing illustrated in FIGS. 3A-3D performed prior. Accordingly, after the processing discussed above with reference to FIGS. 3A-3D, processing may proceed to FIG. 5A.

In FIG. 5A, a first sub-layer 5321 of a second main conductive layer 532 is formed in the openings 318 and 320 and over the second barrier layer 328, in accordance with some embodiments. In some embodiments, the first sub-layer 5321 of the second main conductive layer 532 may extend into the vertical gap 330 (FIG. 3D), such as extending below the bottom of the second barrier layer 328. The first sub-layer 5321 of the second main conductive layer 532 may completely or partially fill the vertical gap 330. In embodiments that the first sub-layer 5321 of the second main conductive layer 532 completely fills the vertical gap 330, the first sub-layer 5321 of the second main conductive layer 532 is in physical contact with the etch stop layer 314. In embodiments that the first sub-layer 5321 of the second main conductive layer 532 partially fills the vertical gap 330, air gap may be formed, such as air gaps being enclosed by the first sub-layer 5321 of the second main conductive layer 532, the second barrier layer 328, the etch stop layer 314, and the first conductive structure 308.

The first sub-layer 5321 of the second main conductive layer 532 may be formed by a PVD process, such as sputtering a first target. The first target may have the desired chemical composition for the first sub-layer 5321 of the second main conductive layer 532. For example, the first target and the first sub-layer 5321 may have includes a low-resistance bulk material doped with a metal dopant. For example, the low-resistance bulk material of the second main conductive layer 332 may be Cu, Co, Ag, Au, Al, W, Zn, alloys thereof. The metal dopant may be Mn, Ti, Co, Ru, Al, Zn, In, or combinations thereof. In some embodiments, the first sub-layer 5321 in the second main conductive layer 332 may have a metal dopant concentration of about 10 at% to about 50 at %. The high concentration of metal dopant can improve the miscibility between the second barrier layer 328 and the bulk material of the second main conductive layer 332, thereby reducing or preventing the second barrier layer 328 being agglomerated as well as reducing or preventing the second main conductive layer 332 being peeled off from the second barrier layer 328. In some embodiments, the first sub-layer 5321 of the second main conductive layer 532 has a thickness of not greater than about 2 nm or less than about 1/10 of a width of the second sub-layer 5322 (FIG. 5B) of the second main conductive layer 532. In some embodiments, the high concentration of the metal dopant may help reduce the diffusion of the bulk material of the second main conductive layer 532 into the etch stop layer 314.

In FIG. 5B, a second sub-layer 5322 of the second main conductive layer 532 is formed and fills in the remaining space of the openings 318 and 320, in accordance with some embodiments. The second sub-layer 5322 of the second main conductive layer 532 may have a material similar to the material of the first sub-layer 5321 of the second main conductive layer 532 but have different compositions. For example, the first sub-layer 5321 and the second sub-layer 5322 are both formed of Cu doped with Mn, and the first sub-layer 5321 has a higher Mn concentration higher than that of the second sub-layer 5322. In some embodiments, the second sub-layer 5322 may have a metal dopant concentration less than 5 at %. The second sub-layer 5322 of the second main conductive layer 532 may be formed by a PVD process, such as sputtering a second target different from the first target. The second target may have the desired chemical composition for the second sub-layer 5322 of the second main conductive layer 532. That is, the second target and the first target may have the same material but different compositions, such as the first target having a higher metal dopant concentration and a lower concentration of the bulk material than the second target. In some embodiments, the second sub-layer 5322 is free of the metal dopant, and the second target is also free of the metal dopant.

The second barrier layer 328, the first sub-layer 5321, and the second sub-layer 5322 of the second main conductive layer 532 may together form second conductive structures 534 in the second dielectric layer 316. For example, the second conductive structures 534 may include one or more first damascene structures 534a and one or more second damascene structures 534b. The first damascene structures 534a may include a conductive via 536 in the opening 318 and a conductive line 538 in the opening 320. The second damascene structure 534b may include the conductive line 538 only.

In FIG. 5C, a planarization process, such as chemical mechanical planarization (CMP) process, may be performed to remove excess portions of the second main conductive layer 532 and the second barrier layer 328 over the upper surface of the second dielectric layer 316. After the planarization process, the conductive lines 538 may have an upper surface level with an upper surface of the second dielectric layer 316 and an upper surface of the second barrier layer 328. Because the first sub-layer 5321 having a high concentration of metal dopant has been formed between the second sub-layer 5322 and the second barrier layer 328, the anneal process as illustrated in FIG. 3G or 4A may be skipped, and metal dopant may be uniformly distributed in the second sub-layer 5322 of the second main conductive layer 532. In some embodiments, an anneal process similar to the anneal process illustrated in FIG. 3G or FIG. 4A can be performed, and the second sub-layer 5322 may therefore have a similar metal dopant concentration profile to those of the second main conductive layer 332 or the second main conductive layer 432.

In FIG. 5D, the processes for forming the second dielectric layer 316 and the second conductive structures 534, including the processes illustrated in FIGS. 3A-3D and FIGS. 5A-5C, are repeated and therefore form an upper-level interconnect structure over the second conductive structures 534 and the second dielectric layer 316, in accordance with embodiments. The upper-level interconnect structure may include the second conductive structures 534 or conductive structures similar to the second conductive structures 534 disposed in the etch stop layer 354 and the third dielectric layer 356.

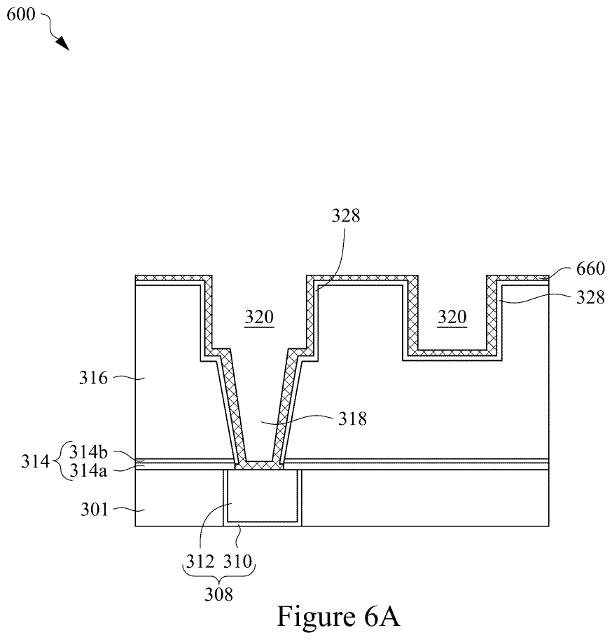

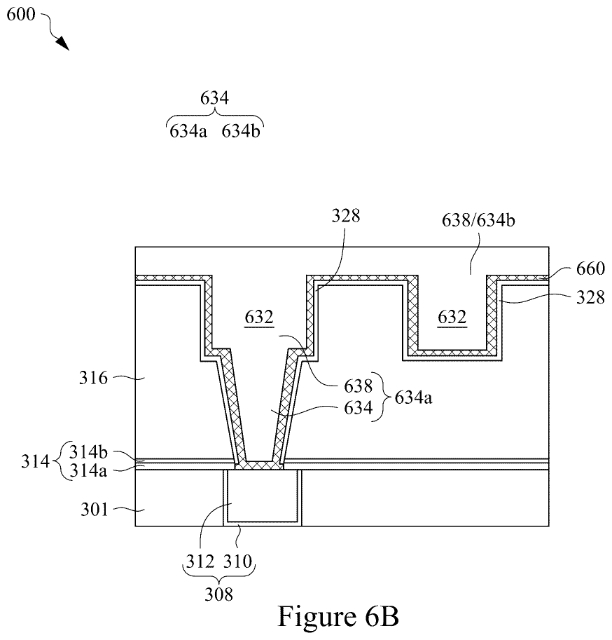

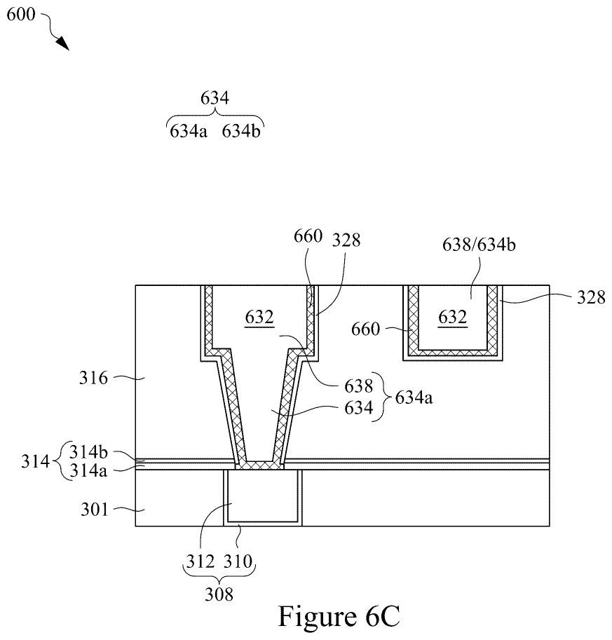

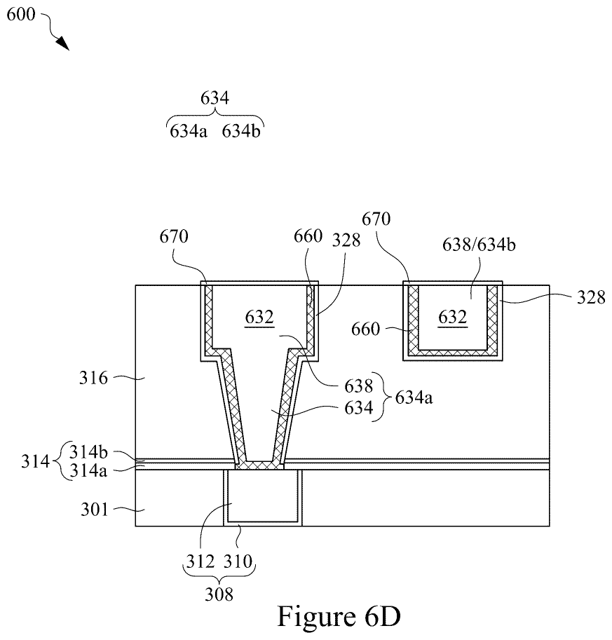

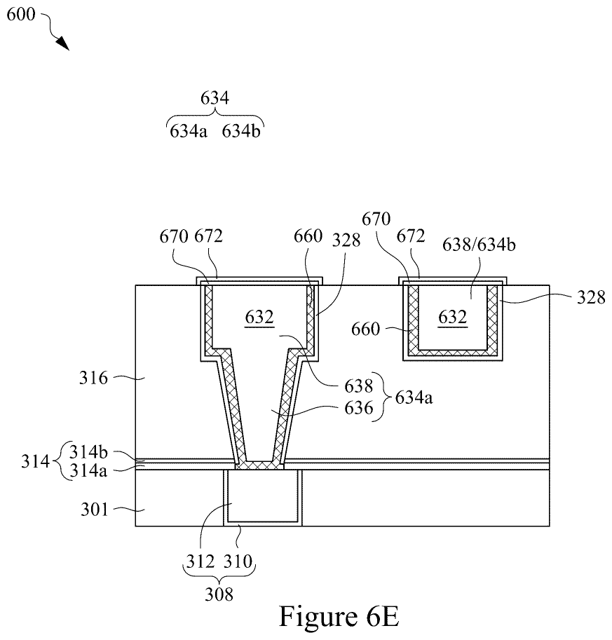

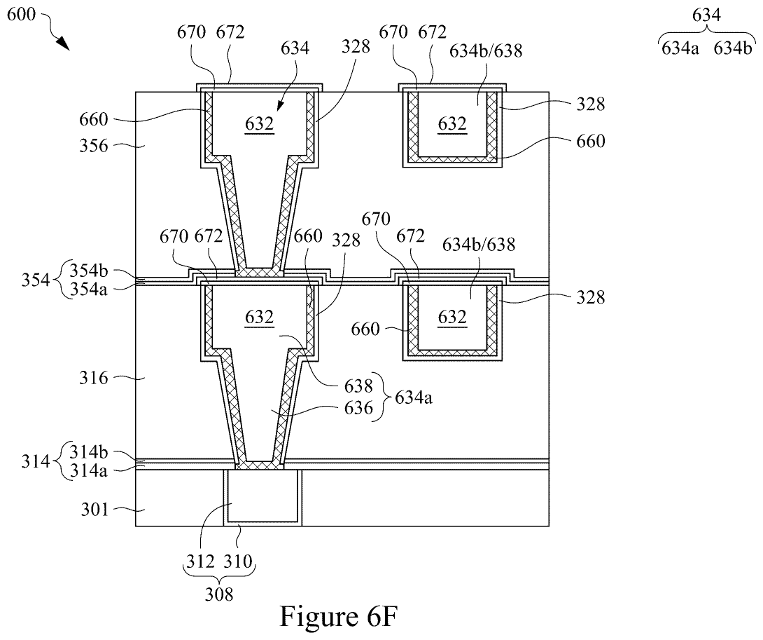

FIGS. 6A-6F are cross-sectional side views of various stages of manufacturing an interconnect structure 600, in accordance with some embodiments. Various embodiments of the interconnect structure 600 may be used to form one or more layers of the interconnect structure 250 shown in FIGS. 1 and 2. The interconnect structure 600 is similar to the interconnect structure 300, 400, or 500, wherein like reference numerals refer to like element. In some embodiments illustrated in FIGS. 6A-6F, a metal liner is formed between the second barrier layer and the second main conductive layer and extends into a gap between the second barrier layer and the first conductive structure. For example, processing of manufacturing the interconnect structure 600 as illustrated in FIGS. 6A-6F assumes the processing illustrated in FIGS. 3A-3D performed prior. Accordingly, after the processing discussed above with reference to FIGS. 3A-3D, processing may proceed to FIG. 6A.

In FIG. 6A, after the second barrier layer 328 is formed and the blocking layer 324 is removed, a metal liner 660 is deposited in openings 318 and 320 and over the second barrier layer 328, in accordance with some embodiments. The metal liner 660 may be formed in a conformal manner. In some embodiments, the metal liner 660 is formed by CVD, ALD, or the like. For example, the metal liner 660 may be formed over the top surface of the first conductive structure 308 and over the second barrier layer 328. In some embodiments, the metal liner 660 extends into the vertical gap 330 (FIG. 3D), such as extending below the second barrier layer 328. The metal liner 660 may completely or partially fill the vertical gap 330. In embodiments that the metal liner 660 completely fills the vertical gap 330, metal liner 660 is in physical contact with the etch stop layer 314. The metal liner 660 may help prevent or reduce the second main conductive layer 632 (FIG. 6B) to diffuse into the etch stop layer 314. In embodiments that the metal liner 660 partially fills the vertical gap 330, air gap may be formed, such as air gaps being enclosed by the metal liner 660, the second barrier layer 328, the etch stop layer 314, and the first conductive structure 308.

In some embodiments, the metal liner 660 is a continuous layer formed of Mn, Ti, Co, Ru, Al, Zn, In, or combinations thereof. For example, the metal liner 660 may be a material similar to the material of the metal dopant as illustrated in the interconnect structure 300. The metal liner 660 may serve as a glue layer to allow better adhesion of the subsequent conductive structures (e.g., second main conductive layer 632) in the openings 318 and 320 to the second barrier layer 328. The metal liner 660 may have a thickness similar to second barrier layer 328. For example, the metal liner 660 may have a thickness ranging from about 1.5 nm to about 3 nm.

In FIG. 6B, a second main conductive layer 632 is filled in the opening 318 and opening 320 to form a second conductive structure 634 together with the second barrier layer 328, in accordance with some embodiments. For example, the second conductive structures 634 may include a first damascene structure 634a and a second damascene structure 634b. The first damascene structure 434a may include a conductive via 636 and a conductive line 638 connected to and over the conductive via 636, and the second damascene structure 634b may include the conductive line 638 only. The conductive via 636 and the conductive line 638 may each include a portion of the second barrier layer 328 and a portion of the second main conductive layer 632 disposed over the second barrier layer 328. The second main conductive layer 632 may be a low-resistance bulk material, such as a metal of Cu, Co, Ag, Au, Al, W, or Zn, without dopants or impurities or only containing negligible amounts of dopants or impurities.

In FIG. 6C, a planarization process, such as a CMP process, is performed to remove excess portions of the second barrier layer 328, the metal liner 660, and the second main conductive layer 632, in accordance with some embodiments. After the planarization process, the upper surfaces of the conductive line 638, the metal liner 660, the second barrier layer 328, and the second dielectric layer 316 are substantially co-planar.

In FIG. 6D, a first barrier cap 670 is selectively formed on the exposed surface of the second conductive structures 634, in accordance with some embodiments. For example, the first barrier cap 670 may be deposited on the exposed surfaces of the second barrier layer 328, the metal liner 660, and the second main conductive layer 632 but not deposited on the top surfaces of the second dielectric layer 316. The first barrier cap 670 may include a material same or similar to the material of metal liner 660, although the first barrier cap 670 and the metal liner 660 may be formed of different materials. For example, the first barrier cap 670 is formed of Mn, Mn, Ti, Co, Ru, Al, Zn, In, or combinations thereof. In some embodiments, the first barrier cap 670 has a substantially uniform thickness, such as about 1.5 nm to about 3 nm. The first barrier cap 670 may have a thickness similar to the thickness of the metal liner 660.

The first barrier cap 670 may be formed by selective deposition, which can be achieved and/or enhanced through the use of ALD process and/or MLD process so that the first barrier cap 670 has the characteristic or property of being specific in bonding with the second conductive structure 634 through self-limiting surface reactions. Alternatively, a mask (not shown) may be used to block the first barrier cap 670 being formed on the upper surface of the second dielectric layer 316. The mask may include a material similar to those of the blocking layer 324 and may be formed by processes similar to those of the blocking layer 324. The mask may be removed using, such as thermal degradation or plasma bombardment, or other suitable process, after first barrier cap 670 is formed.

In FIG. 6E, a second barrier cap 672 is selectively formed over the first barrier cap 670, in accordance with some embodiments. The second barrier cap 672 may include a material similar to those of the second barrier layer 328, although second barrier cap 672 may include a material different from the second barrier layer 328. For example, the second barrier cap 672 may be a continuous layer of Ru or Mo. In some embodiments, the second barrier cap 672 has a substantially uniform thickness, such as about 1.5 nm to about 3 nm.

The second barrier cap 672 may be formed by selective deposition, which can be achieved and/or enhanced through the use of ALD process and/or MLD process so that the second barrier cap 672 has the characteristic or property of being specific in bonding with the second conductive structure 634 through self-limiting surface reactions. In embodiments that the second barrier cap 672 is formed by the self-limiting surface reactions, the second barrier cap 672 may also extend to cover the sidewalls of the first barrier cap 670, as illustrated in FIG. 6E. In some embodiments, the selective deposition may be formed by forming a mask on the top surface of the second dielectric layer 316 first. The mask (not shown) may be selectively deposited on the dielectric surfaces, such as the top surface of the second dielectric layer 316, but not deposited on metallic surfaces. As a result, the mask may be used to block the second barrier cap 672 being formed on the top surface of the second dielectric layer 316. The mask may include a material similar to those of the blocking layer 324 and may be formed by processes similar to those of the blocking layer 324. The mask may be removed using, such as thermal degradation or plasma bombardment, or other suitable process, after the second barrier cap 672 is formed. Although not shown in Figures, in some embodiments that the mask is used, the second barrier cap 672 is deposited only on the top surface of the first barrier cap 670 but not extends to cover sidewalls of the first barrier cap 670.

In FIG. 6F, the processes for forming the second dielectric layer 316 and the second conductive structures 634, including the processes illustrated in FIGS. 3A-3D and FIGS. 6A-6E, are repeated and therefore form an upper-level interconnect structure over the second conductive structures 634 and the second dielectric layer 316, in accordance with embodiments. The upper-level interconnect structure may include the second conductive structures 634 in the third dielectric layer 356 and the etch stop layer 354. The etch stop layer 354 and the third dielectric layer 356 each includes a material and may be formed by processes similar to those of the etch stop layer 314 and those of the second dielectric layer 316, respectively.

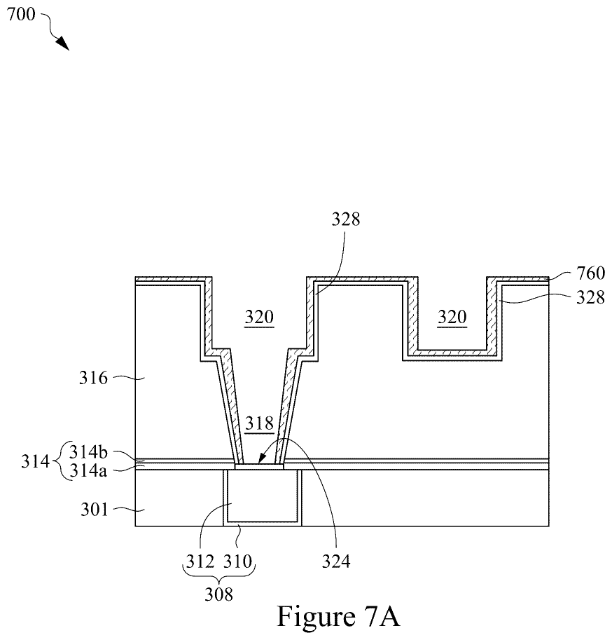

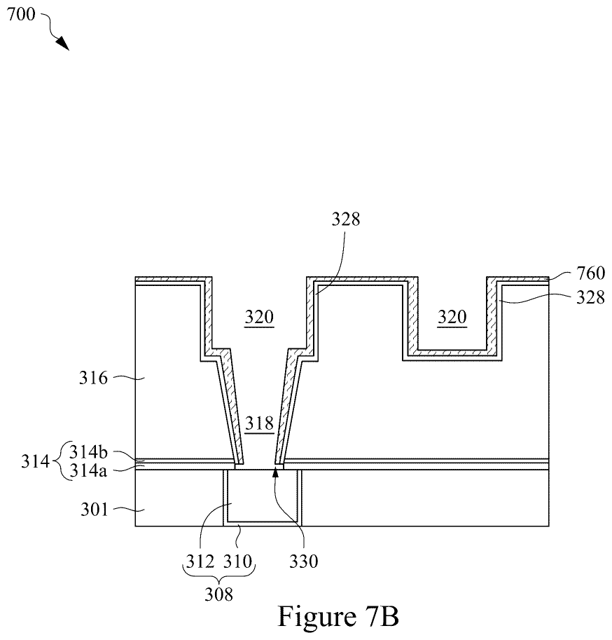

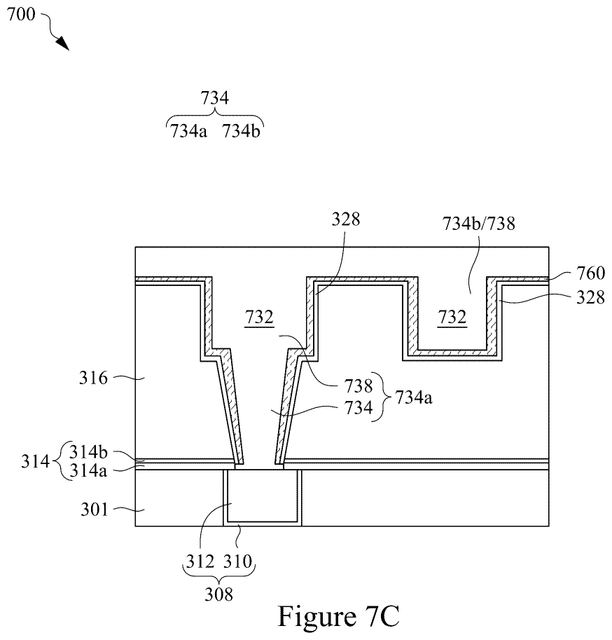

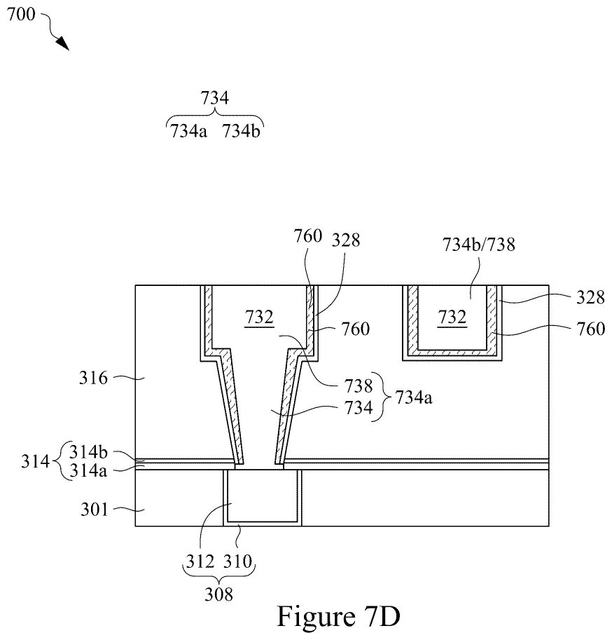

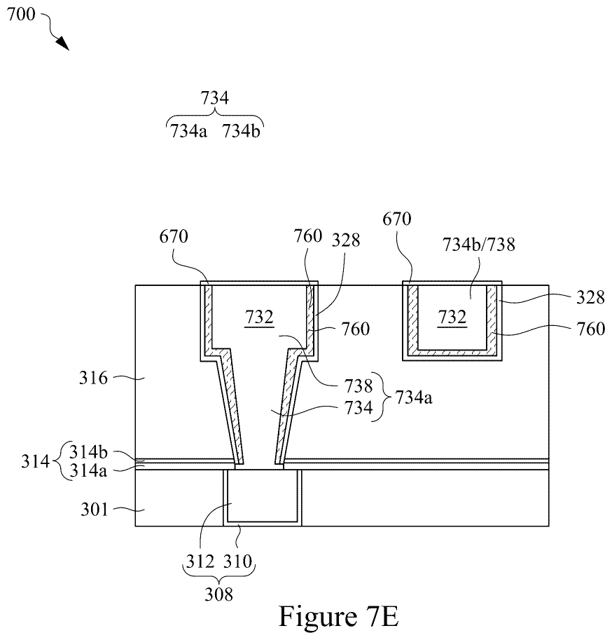

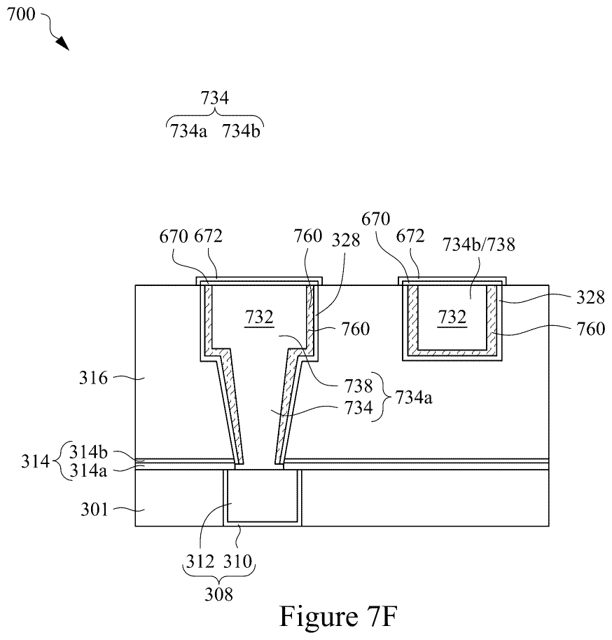

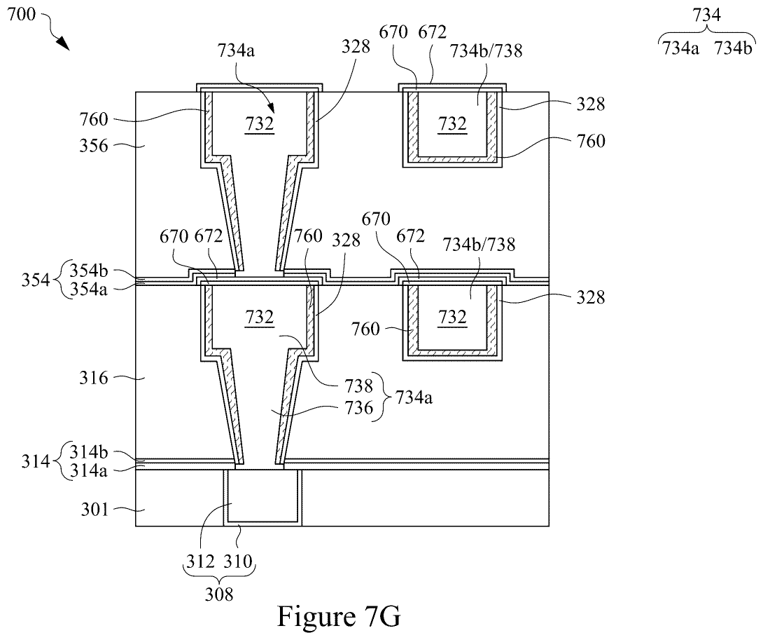

FIGS. 7A-7G are cross-sectional side views of various stages of manufacturing an interconnect structure 700, in accordance with some embodiments. Various embodiments of the interconnect structure 700 may be used to form one or more layers of the interconnect structure 250 shown in FIGS. 1 and 2. The interconnect structure 700 is similar to the interconnect structure 300, 400, 500, or 600, wherein like reference numerals refer to like element. In some embodiments illustrated in FIGS. 7A-7G, a metal liner is formed between the second barrier layer and the second main conductive layer. For example, processing of manufacturing the interconnect structure 700 as illustrated in FIGS. 7A-7G assumes the processing illustrated in FIGS. 3A-3C performed prior. Accordingly, after the processing discussed above with reference to FIGS. 3A-3C, processing may proceed to FIG. 7A.

In FIG. 7A, after the second barrier layer 328 is formed, a metal liner 760 is deposited in openings 318 and 320 and over the second barrier layer 328, in accordance with some embodiments. With the blocking layer 324 being formed on the metallic top surfaces of the first conductive structure 308, the metal liner 760 is selectively formed over the second barrier layer 328 and not formed over the blocking layer 324. The selective deposition of the metal liner 760 can be achieved and/or enhanced through the use of ALD process and/or MLD process. The metal liner 760 may be formed in a conformal manner. In some embodiments, the metal liner 760 is a continuous layer formed of Mn, Ti, Co, Ru, Al, Zn, In, or combinations thereof. For example, the metal liner 760 may be a material similar to the material of the metal dopant as illustrated in the interconnect structure 300. The metal liner 760 may serve as a glue layer to allow better adhesion of the subsequent conductive structures (e.g. second main conductive layer 732) in the openings 318 and 320 to the second barrier layer 328. The metal liner 760 may have a thickness similar to second barrier layer 328. For example, the metal liner 760 may have a thickness ranging from about 1.5 nm to about 3 nm.

In FIG. 7B, after the formation of the second barrier layer 328 and the metal liner 760, the blocking layer 324 is removed to expose the top surface of the first conductive structure 308. The blocking layer 324 may be removed using thermal degradation or plasma bombardment, or other suitable process. The removal process does not substantially affect the second barrier layer 328 and the metal liner 760. With the removal of the blocking layer 324, a vertical gap 330 between the top surface of the first conductive structure 308 and the second barrier layer 328, in accordance with some embodiments. In some embodiments, the vertical gap 330 is small and can be negligible.

In FIG. 7C, a second main conductive layer 732 is filled in the opening 318 and opening 320 to form a second conductive structure 734 together with the second barrier layer 328, in accordance with some embodiments. In other words, the second barrier layer 328 and the second main conductive layer 732 in the opening 318 may form the conductive via 736, and the second barrier layer 328 and the second main conductive layer 732 in the opening 320 may form a conductive line 638. The second conductive structure 734 may include one or more first damascene structures 734a that includes the conductive via 736 in the opening 318 and the conductive line 738 in the opening 320 and/or one or more second damascene structure 734b that includes the conductive line 738 only.

The second main conductive layer 732 may or may not extend into the vertical gap 330, such as extending below the second barrier layer 328. For example, the second main conductive layer 732 may seal the entrance of the vertical gap 330 and forms air gaps (not shown) between the second main conductive layer 732 and the etch stop layer 314. The second main conductive layer 732 may be a low-resistance bulk material, such as a metal of Cu, Co, Ag, Au, Al, W, or Zn, without dopants or impurities or only containing negligible amounts of dopants or impurities.

In FIG. 7D, a planarization process, such as a CMP process, is performed to remove excess portions of the second barrier layer 328, the metal liner 760, the second main conductive layer 732, in accordance with some embodiments. After the planarization process, the upper surfaces of the conductive line 738, the metal liner 760, the second barrier layer 328, and the second dielectric layer 316 are substantially co-planar.

In FIG. 7E, a first barrier cap 670 is selectively formed on the exposed surface of the second conductive structures 734, in accordance with some embodiments. For example, the first barrier cap 670 may be deposited on the exposed surfaces of the second barrier layer 328, the metal liner 760, and the second main conductive layer 732 but not deposited over the upper surfaces of the second dielectric layer 316.

In FIG. 7F, a second barrier cap 672 is selectively formed on the first barrier cap 670, in accordance with some embodiments. The second barrier cap 672 may be formed by selective deposition, which can be achieved and/or enhanced through the use of ALD process and/or MLD process so that the second barrier cap 672 has the characteristic or property of being specific in bonding with the second conductive structure 634 through self-limiting surface reactions. In embodiments that the second barrier cap 672 is formed by the self-limiting surface reactions, the second barrier cap 672 may also extend to cover the sidewalls of the first barrier cap 670, as illustrated in FIG. 7E. In some embodiments, the selective deposition may be formed by forming a mask on the top surface of the second dielectric layer 316 first. The mask (not shown) may be selectively deposited on the dielectric surfaces, such as the top surface of the second dielectric layer 316, but not deposited on metallic surfaces. As a result, the mask may be used to block the second barrier cap 672 being formed on the top surface of the second dielectric layer 316. In some embodiments that the mask is used, the second barrier cap 672 is deposited only on the top surface of the first barrier cap 670 but not extends to cover sidewalls of the first barrier cap 670.

In FIG. 7G, the processes for forming the second dielectric layer 316 and the second conductive structures 634, including the processes illustrated in FIGS. 3A-3C and FIGS. 7A-7F, are repeated and therefore form an upper-level interconnect structure over the second conductive structures 734 and the second dielectric layer 316, in accordance with embodiments. The upper-level interconnect structure may include the second conductive structures 734 in the third dielectric layer 356 and the etch stop layer 354. The etch stop layer 354 and the third dielectric layer 356 each includes a material and may be formed by processes similar to those of the etch stop layer 314 and those of the second dielectric layer 316, respectively.

Although not described in detail above, the first conductive structure 308 in the interconnect structure 300, 400, 500, 600, or 700 can be replaced with any one of the second conductive structures 334, 434, 534, 634, or 734, in accordance with some embodiments.

Some embodiments relate to interconnection structures with improved thermal stability with excellent RC delay. Particularly, the embodiments of the present disclosure provide a metal dopant or a metal liner that can effectively reduce the thickness of the barrier layer and therefore can provide more volume for main conductive layer in fine-pitch conductive lines. With the metal dopant or metal liner, the barrier layer having the reduce thickness may still provide sufficient protection for preventing the diffusion out of the main conductive layer as well as have a good thermal stability.

In an embodiment, an interconnect structure includes a first conductive structure disposed in a first dielectric layer, wherein the first conductive structure includes a first barrier layer and a first main conductive layer; a second dielectric layer disposed over the first dielectric layer; and a second conductive structure disposed in the second dielectric layer and over the first conductive structure, wherein the second conductive structure includes: a second barrier layer including a first conductive material selected from Ru or Mo; a second main conductive layer disposed over the second barrier layer and including a second conductive material having an electrical resistivity lower than the first conductive material, wherein an upper surface of the second dielectric layer is coplanar with an upper surface of the second barrier layer and an upper surface of the second main conductive layer; and a third conductive material being a dopant doped in the second main conductive layer or being a continuous layer between the second main conductive layer and the second barrier layer, wherein the third conductive material is selected from Mn, Ti, Co, Ru, Al, Zn, In, or combinations thereof. In an embodiment, the interconnect structure further includes: a barrier cap disposed over the upper surface of the second barrier layer and the upper surface of the second main conductive layer, wherein the barrier cap includes the first conductive material; a third dielectric layer disposed over the second dielectric layer and the barrier cap; and a third conductive structure disposed in the third dielectric layer and over the barrier cap. In an embodiment, the barrier cap has a first thickness over the upper surface of the second barrier layer and a second thickness over the upper surface of the second main conductive layer, wherein the first thickness is less than the second thickness. In an embodiment, when the third conductive material is a dopant doped in the second main conductive layer, the third conductive material is also partially doped in the first main conductive layer. In an embodiment, the interconnect further includes a vertical gap formed between the second barrier layer and the first conductive structure, wherein the second main conductive layer extends into the vertical gap, wherein when the third conductive material is a dopant doped in the second main conductive layer, a concentration of the third conductive material in the vertical gap is greater than a concentration of a center portion of the third conductive material in the second main conductive layer. In an embodiment, the interconnect structure further includes a vertical gap formed between the second barrier layer and the first conductive structure, wherein when the third conductive material is a continuous layer, the continuous layer fills the vertical gap.

In an embodiment, an interconnect structure includes: a first conductive structure disposed in a first dielectric layer; a second dielectric layer disposed over the first dielectric layer; a second conductive structure disposed in the second dielectric layer and over the first conductive structure, wherein the second conductive structure includes: a first barrier layer disposed on the second dielectric layer; and a doped main conductive layer disposed on the first barrier layer, wherein the doped main conductive layer comprises an edge portion adjacent the first barrier layer and a center region, and a dopant concentration of the edge portion is greater than a dopant concentration of the center region. In an embodiment, the first barrier layer is selected from Ru or Mo. In an embodiment, the doped main conductive layer further comprises a first conductive material and a metal dopant doped in the first conductive material. In an embodiment, the metal dopant comprises Mn, Ti, Co, Ru, Al, Zn, In, or combinations thereof. In an embodiment, the interconnect structure further includes a barrier cap disposed on an upper surface of the first barrier layer and an upper surface of the doped main conductive layer, wherein the barrier cap has a same material as the first barrier layer. In an embodiment, the barrier cap has a first thickness on the upper surface of the first barrier layer and a second thickness on the upper surface of the doped main conductive layer, wherein the second thickness is greater than the first thickness. In an embodiment, the interconnect structure further includes conductive grains embedded in the first barrier layer.

In an embodiment, a method for forming an interconnect structure is provided, and the method includes: forming a first conductive structure in a first dielectric layer; forming a second dielectric layer over the first conductive structure and the first dielectric layer; forming an opening in the second dielectric layer to expose the first conductive structure and side surfaces of the second dielectric layer; forming a barrier layer on the side surfaces of the second dielectric layer, wherein the barrier layer comprises a first conductive material selected from Ru or Mo; forming a main conductive layer over the barrier layer, wherein the main conductive layer comprises a second conductive material different from the first conductive material; forming a third conductive material, wherein the third conductive material is a dopant doped in the main conductive layer and deposited simultaneously with the main conductive layer or a continuous layer or a continuous layer deposited over the barrier layer before forming the third conductive material, wherein the third conductive material is selected from Mn, Ti, Co, Ru, Al, Zn, In, or combinations thereof; and forming a barrier cap over the barrier layer and the main conductive layer, wherein the barrier cap comprises the first conductive material. In an embodiment, the method further includes forming a blocking layer over the first conductive structure before forming the barrier layer. In an embodiment, the method further includes removing the blocking layer after forming the barrier layer. In an embodiment, removing the blocking layer forms a gap between the barrier layer and the first conductive structure, and when the third conductive material is a continuous layer, the continuous layer fills the gap. In an embodiment, when the third conductive material is a dopant doped in the main conductive layer and deposited simultaneously with the main conductive layer, the method further comprising: forming a first portion of the main conductive layer by sputtering a first target; and forming a second portion of the main conductive layer over the first portion of the main conductive layer by sputtering a second target, wherein the first target and the second target have a same material but different compositions. In an embodiment, wherein the first target has a concentration of the third conductive material greater than the second target. In an embodiment, wherein when the third conductive material is a dopant doped in the main conductive layer and deposited simultaneously with the main conductive layer, the method further comprises performing an anneal process to drive the third conductive material to diffuse toward edges of the main conductive layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. An interconnect structure, comprising:
a first conductive structure disposed in a first dielectric layer, wherein the first conductive structure comprises a first barrier layer and a first main conductive layer;
a second dielectric layer disposed over the first dielectric layer; and
a second conductive structure disposed in the second dielectric layer and over the first conductive structure, wherein the second conductive structure comprises:
a second barrier layer comprising a first conductive material selected from Ru or Mo;
a second main conductive layer disposed over the second barrier layer and comprising a second conductive material having an electrical resistivity lower than the first conductive material, wherein an upper surface of the second dielectric layer is coplanar with an upper surface of the second barrier layer and an upper surface of the second main conductive layer; and
a third conductive material being a dopant doped in the second main conductive layer or being a continuous layer between the second main conductive layer and the second barrier layer, wherein the third conductive material is selected from Mn, Ti, Co, Ru, Al, Zn, In, or combinations thereof.

2. The interconnect structure of claim 1, further comprises:
a barrier cap disposed over the upper surface of the second barrier layer and the upper surface of the second main conductive layer, wherein the barrier cap comprises the first conductive material;
a third dielectric layer disposed over the second dielectric layer and the barrier cap; and
a third conductive structure disposed in the third dielectric layer and over the barrier cap.

3. The interconnect structure of claim 2, wherein the barrier cap has a first thickness over the upper surface of the second barrier layer and a second thickness over the upper surface of the second main conductive layer, wherein the first thickness is less than the second thickness.

4. The interconnect structure of claim 1, wherein when the third conductive material is a dopant doped in the second main conductive layer, the third conductive material is also partially doped in the first main conductive layer.

5. The interconnect structure of claim 1, further comprising a vertical gap formed between the second barrier layer and the first conductive structure, wherein the second main conductive layer extends into the vertical gap, wherein when the third conductive material is a dopant doped in the second main conductive layer, a concentration of the third conductive material in the vertical gap is greater than a concentration of a center portion of the third conductive material in the second main conductive layer.

6. The interconnect structure of claim 1, further comprising a vertical gap formed between the second barrier layer and the first conductive structure, wherein when the third conductive material is a continuous layer, the continuous layer fills the vertical gap.

7. An interconnect structure, comprising:
a first conductive structure disposed in a first dielectric layer;
a second dielectric layer disposed over the first dielectric layer;
a second conductive structure disposed in the second dielectric layer and over the first conductive structure, wherein the second conductive structure comprises:
a first barrier layer disposed on the second dielectric layer; and
a doped main conductive layer disposed on the first barrier layer, wherein the doped main conductive layer comprises an edge portion adjacent the first barrier layer and a center region, and a dopant concentration of the edge portion is greater than a dopant concentration of the center region.

8. The interconnect structure of claim 7, wherein the first barrier layer is selected from Ru or Mo.

9. The interconnect structure of claim 7, wherein the doped main conductive layer further comprises a first conductive material and a metal dopant doped in the first conductive material.

10. The interconnect structure of claim 9, wherein the metal dopant comprises Mn, Ti, Co, Ru, Al, Zn, In, or combinations thereof.

11. The interconnect structure of claim 7, further comprising a barrier cap disposed on an upper surface of the first barrier layer and an upper surface of the doped main conductive layer, wherein the barrier cap has a same material as the first barrier layer.

12. The interconnect structure of claim 11, wherein the barrier cap has a first thickness on the upper surface of the first barrier layer and a second thickness on the upper surface of the doped main conductive layer, wherein the second thickness is greater than the first thickness.

13. The interconnect structure of claim 7, further comprising conductive grains embedded in the first barrier layer.

14. A method for forming an interconnection structure, the method comprising:
forming a first conductive structure in a first dielectric layer;
forming a second dielectric layer over the first conductive structure and the first dielectric layer;
forming an opening in the second dielectric layer to expose the first conductive structure and side surfaces of the second dielectric layer;
forming a barrier layer on the side surfaces of the second dielectric layer, wherein the barrier layer comprises a first conductive material selected from Ru or Mo;
forming a main conductive layer over the barrier layer, wherein the main conductive layer comprises a second conductive material different from the first conductive material;
forming a third conductive material, wherein the third conductive material is a dopant doped in the main conductive layer and deposited simultaneously with the main conductive layer or a continuous layer or a continuous layer deposited over the barrier layer before forming the third conductive material, wherein the third conductive material is selected from Mn, Ti, Co, Ru, Al, Zn, In, or combinations thereof; and
forming a barrier cap over the barrier layer and the main conductive layer, wherein the barrier cap comprises the first conductive material.

15. The method of claim 14, further comprising forming a blocking layer over the first conductive structure before forming the barrier layer.

16. The method of claim 15, further comprising removing the blocking layer after forming the barrier layer.

17. The method of claim 16, wherein removing the blocking layer forms a gap between the barrier layer and the first conductive structure, and when the third conductive material is a continuous layer, the continuous layer fills the gap.

18. The method of claim 16, wherein when the third conductive material is a dopant doped in the main conductive layer and deposited simultaneously with the main conductive layer, the method further comprising:
forming a first portion of the main conductive layer by sputtering a first target; and
forming a second portion of the main conductive layer over the first portion of the main conductive layer by sputtering a second target, wherein the first target and the second target have a same material but different compositions.

19. The method of claim 18, wherein the first target has a concentration of the third conductive material greater than the second target.

20. The method of claim 14, wherein when the third conductive material is a dopant doped in the main conductive layer and deposited simultaneously with the main conductive layer, the method further comprises performing an anneal process to drive the third conductive material to diffuse toward edges of the main conductive layer.
